(19) United States
(12) Patent Application Publication
(10) Pub. No.: US 2015/0020848 A1
(43) Pub. Date: Jan. 22, 2015

(54) Systems and Methods for In-Situ Wafer Edge and Backside Plasma Cleaning

(71) Applicant: Lam Research Corporation, Fremont, CA (US)

(72) Inventors: Keechan Kim, Dublin, CA (US); Jack Chen, San Francisco, CA (US); Yunsang Kim, Monte Sereno, CA (US); Kenneth George Delfin, Meridian, IN (US)

(73) Assignee: LAM RESEARCH CORPORATION, Fremont, CA (US)

(21) Appl. No.: 14/032,165

(22) Filed: Sep. 19, 2013

Related U.S. Application Data
(60) Provisional application No. 61/856,613, filed on Jul. 19, 2013.

(51) Int. Cl. H01L 21/02; H01L 21/67

(52) U.S. Cl. CPC H01L 21/02057; H01L 21/02087; H01L 21/0209; H01L 21/67017
USPC 134/1.2; 156/345.47; 156/345.34

(57) ABSTRACT

A lower electrode plate receives radiofrequency power. A first upper plate is positioned parallel to and spaced apart from the lower electrode plate. A grounded second upper plate is positioned next to the first upper plate. A dielectric support provides support of a workpiece within a region between the lower electrode plate and the first upper plate. A purge gas is supplied at a central location of the first upper plate. A process gas is supplied to a periphery of the first upper plate. The dielectric support positions the workpiece proximate and parallel to the first upper plate, such that the purge gas flows over a top surface of the workpiece so as to prevent the process gas from flowing over the top surface of the workpiece, and so as to cause the process gas to flow around a peripheral edge of the workpiece and below the workpiece.

### CLAIM OF PRIORITY

This application claims priority under 35 U.S.C. 119(e) to U.S. Provisional Patent Application No. 61/856,613, filed Jul. 19, 2013, entitled “Systems and Methods for In-situ Wafer Edge and Backside Plasma Cleaning,” the disclosure of which is incorporated herein by reference in its entirety.

### BACKGROUND

During semiconductor chip fabrication, a substrate is subjected to a series of material deposition and removal processes to buildup patterns of various conductive and dielectric materials on the substrate that ultimately form a functional integrated circuit device. During the various material removal processes, i.e., etching processes, etch byproduct materials can build up at the edge region of the substrate where plasma density is often lower. The etch byproduct materials can be of any material type used in the fabrication of the semiconductor chip, and often include polymers comprised of carbon, oxygen, nitrogen, fluorine, among others. As the etch byproduct material builds up near the peripheral edge of the substrate, the etch byproduct material can become unstable and flake/detach from the substrate, thereby becoming a source for potential material contamination of other portions of the substrate where semiconductor chips are being fabricated. In addition, during the various fabrication processes, byproduct materials can adhere to any exposed portions of the backside surface of the substrate, thereby becoming another source for potential material contamination of critical portions of the substrate. Therefore, during the fabrication of semiconductor devices on the substrate, it is necessary to remove problematic byproduct materials from the peripheral edge of the substrate and from the backside of the substrate. It is within this context that the present invention arises.

### SUMMARY

In one embodiment, a semiconductor processing system is disclosed. The system includes a lower electrode plate and a radiofrequency power supply connected to supply radiofrequency power to the lower electrode plate. The system also includes a dielectric upper plate positioned parallel to and spaced apart from the lower electrode plate. The system also includes an upper electrode plate positioned next to the dielectric upper plate, such that the dielectric upper plate is located between the lower electrode plate and the upper electrode plate. The upper electrode plate is electrically connected to a reference ground potential. The system also includes a dielectric support defined to support a workpiece in an electrically isolated manner within a region between the lower electrode plate and the dielectric upper plate. The system also includes a purge gas supply channel formed to supply a purge gas to the region between the lower electrode plate and the dielectric upper plate at a central location of the dielectric upper plate. The system also includes a process gas supply channel formed to supply a process gas to the region between the lower electrode plate and the dielectric upper plate at a periphery of the dielectric upper plate. The dielectric support is defined to position the workpiece at a position proximate to and substantially parallel to the dielectric upper plate, such that the purge gas is made to flow from the purge gas supply channel over a top surface of the workpiece between the dielectric upper plate and the top surface of the workpiece, so as to prevent the process gas from flowing over the top surface of the workpiece, and so as to cause the process gas to flow around a peripheral edge of the workpiece and below the workpiece into a region between the lower electrode plate and a bottom surface of the workpiece, when the workpiece is present on the dielectric support.

In one embodiment, a method is disclosed for plasma cleaning a peripheral region and a bottom surface of a workpiece. The method includes positioning the bottom surface of the workpiece on a dielectric support defined to support the workpiece in an electrically isolated manner within a region between an upper surface of a lower electrode plate and a lower surface of a dielectric upper plate. An upper electrode plate is positioned next to an upper surface of the dielectric upper plate. The lower electrode plate is connected to receive radiofrequency power. The upper electrode plate is electrically connected to a reference ground potential. The method also includes positioning the dielectric support such that a top surface of the workpiece is separated from the lower surface of the dielectric upper plate by a narrow gap, and such that an open region exists between the bottom surface of the workpiece and the upper surface of the lower electrode plate. The method also includes flowing a purge gas to a central location within the narrow gap between the top surface of the workpiece and the lower surface of the dielectric upper plate, such that the purge gas flows through the narrow gap in a direction away from the central location toward a periphery of the workpiece. The method also includes flowing a process gas to a peripheral region of the workpiece located outside the narrow gap. The process gas flows into the region between the bottom surface of the workpiece and the upper surface of the lower electrode plate. The method also includes supplying radiofrequency power to the lower electrode plate so as to transform the process gas into a plasma around the peripheral region of the workpiece and within the region between the bottom surface of the workpiece and the upper surface of the lower electrode plate.

In one embodiment, a semiconductor processing system is disclosed. The system includes a lower showerhead electrode plate having an interior region for transforming a process gas into a plasma. The lower showerhead electrode plate has a number of vents extending from an upper surface of the lower showerhead plate to the interior region. The system also includes a process gas supply channel is formed to supply the process gas to the interior region of the lower showerhead electrode plate. The system also includes a radiofrequency power supply connected to supply radiofrequency power to the lower showerhead electrode plate so as to transform the process gas into the plasma within the interior region of the lower showerhead electrode plate. The system also includes a first upper plate positioned parallel to and spaced apart from the lower showerhead electrode plate. The system also includes a second upper plate positioned next to the first upper plate such that the first upper plate is located between the lower showerhead electrode plate and the second upper plate. The second upper plate is electrically connected to a reference ground potential. The system also includes a dielectric edge ring that has an annular shape with an upper surface defined to contact and support a peripheral region of a bottom surface of a workpiece. The dielectric edge ring is defined to support the workpiece in an electrically isolated manner within a region between the upper surface of the lower showerhead electrode plate and a lower surface of the first upper plate. The system also includes a purge gas supply channel formed to supply a purge gas to the region between the upper surface of the lower showerhead electrode plate and the lower surface of the first upper plate at a central location of the first upper plate. The dielectric edge ring is defined to position the workpiece proximate to and substantially parallel to the first upper plate, such that the purge gas is made to flow from the purge gas supply channel over a top surface of the workpiece, between the lower surface of the first upper plate and the top surface of the workpiece, so as to prevent reactive constituents of the plasma from reaching the top surface of the workpiece, when the workpiece is present on the dielectric edge ring.

In one embodiment, a method is disclosed for plasma cleaning a bottom surface of a workpiece. The method includes positioning the workpiece on a dielectric edge ring that has an annular shape with an upper surface defined to contact and support a peripheral region of the bottom surface of the workpiece. The dielectric edge ring is defined to support the workpiece in an electrically isolated manner within a region between an upper surface of a lower showerhead electrode plate and a lower surface of a first upper plate. A second upper plate is positioned next to an upper surface of the first upper plate. The lower showerhead electrode plate is connected to receive radiofrequency power. The second upper plate electrically is connected to a reference ground potential. The method also includes positioning the dielectric edge ring such that a top surface of the workpiece is separated from the lower surface of the first upper plate by a narrow gap, and such that an open region exists between the bottom surface of the workpiece located inside the dielectric edge ring and the upper surface of the lower showerhead electrode plate. The method also includes flowing a purge gas to a central location within the narrow gap, such that the purge gas flows through the narrow gap in a direction away from the central location toward a periphery of the workpiece. The method also includes flowing a process gas to an interior region of the lower showerhead electrode plate. The method also includes supplying radiofrequency power to the lower showerhead electrode plate so as to transform the process gas into a plasma within the interior region of the lower showerhead electrode plate, whereby reactive constituents of the plasma flow through vents from the interior region of the lower showerhead electrode plate into the open region between the bottom surface of the workpiece located inside the dielectric edge ring and the upper surface of the lower showerhead electrode plate.

Other aspects and advantages of the invention will become more apparent from the following detailed description, taken in conjunction with the accompanying drawings, illustrating by way of example the present invention.

### BRIEF DESCRIPTION OF THE DRAWINGS

FIG. 1A shows a semiconductor processing system, in accordance with one embodiment of the present invention.

FIG. 1B shows a horizontal cross-sectional view A-A as denoted in FIG. 1A, in accordance with one embodiment of the present invention.

FIG. 1C shows a variation of the semiconductor processing system in which the process gas supply channel is defined to pass through the dielectric upper plate a various locations about the periphery of the dielectric upper plate, in accordance with one embodiment of the present invention.

FIG. 1D shows the horizontal cross-sectional view A-A as denoted in FIG. 1C, in accordance with one embodiment of the present invention.

FIG. 1E shows a variation of the semiconductor processing system of FIG. 1A defined to use a remote plasma source, in accordance with one embodiment of the present invention.

FIG. 1F shows the semiconductor processing system of FIG. 1A in a configuration in which the workpiece is lowered to rest on the lower electrode assembly in order to perform plasma processing of the peripheral edge of the workpiece, in accordance with one embodiment of the present invention.

FIG. 2A shows a semiconductor processing system, in accordance with one embodiment of the present invention.

FIG. 2B shows the horizontal cross-sectional view B-B as denoted in FIG. 2A, in accordance with one embodiment of the present invention.

FIG. 2C shows an example embodiment in which the dielectric edge ring is defined as a stack of annular shaped rings separated from each other by spaces that form the vents, in accordance with one embodiment of the present invention.

FIG. 2D shows a variation of the semiconductor processing system of FIG. 2A defined to use a remote plasma source, in accordance with one embodiment of the present invention.

FIG. 2E shows the semiconductor processing system of FIG. 2A in a configuration in which the workpiece is lowered to rest on the lower electrode assembly in order to perform plasma processing of the peripheral edge of the workpiece, in accordance with one embodiment of the present invention.

FIG. 3A shows a semiconductor processing system, in accordance with one embodiment of the present invention.

FIG. 3B shows a variation of the semiconductor processing system of FIG. 3A defined to use a remote plasma source, in accordance with one embodiment of the present invention.

FIG. 3C shows the semiconductor processing system of FIG. 3A in a configuration in which the workpiece is lowered to rest on the lower electrode assembly in order to perform plasma processing of the peripheral edge of the workpiece, in accordance with one embodiment of the present invention.

FIG. 4 shows a semiconductor processing system that is a variation of the system described with regard to FIG. 3A, in accordance with one embodiment of the present invention.

FIGS. 5A and 5B show a semiconductor processing system that is also a variation of the system described with regard to FIG. 3A, in accordance with one embodiment of the present invention.

FIG. 5C shows a variation of the semiconductor processing system of FIG. 5A defined to use a remote plasma source, in accordance with one embodiment of the present invention.

FIG. 6 shows a flowchart of a method for plasma cleaning a bottom surface of a workpiece, in accordance with one embodiment of the present invention.

FIG. 7 shows a flowchart of a method for plasma cleaning a bottom surface of a workpiece, in accordance with one embodiment of the present invention.

FIG. 8 shows a flowchart of a method for performing both a bevel edge plasma cleaning process and backside cleaning process on a workpiece within a common plasma processing system, in accordance with one embodiment of the present invention.

### DETAILED DESCRIPTION

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

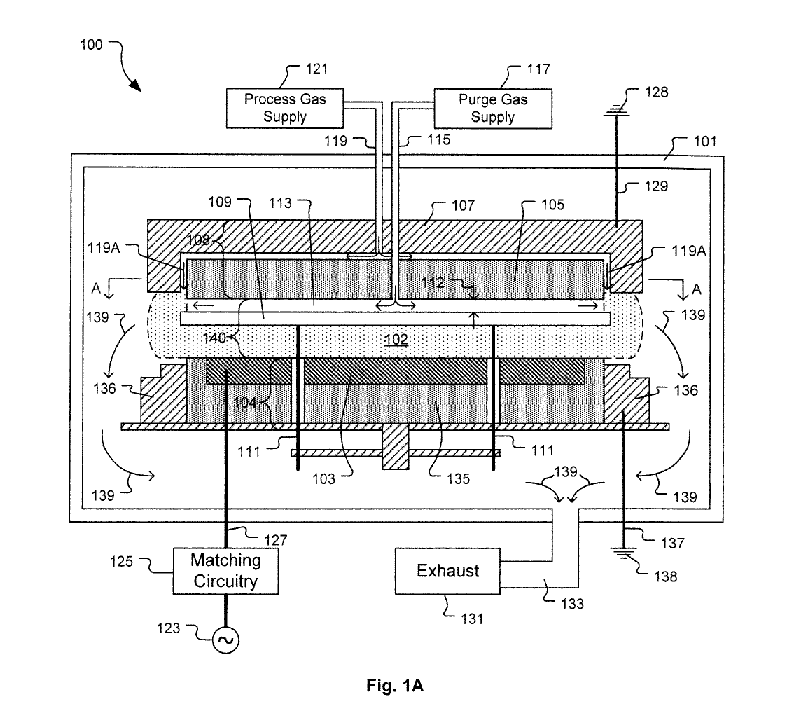

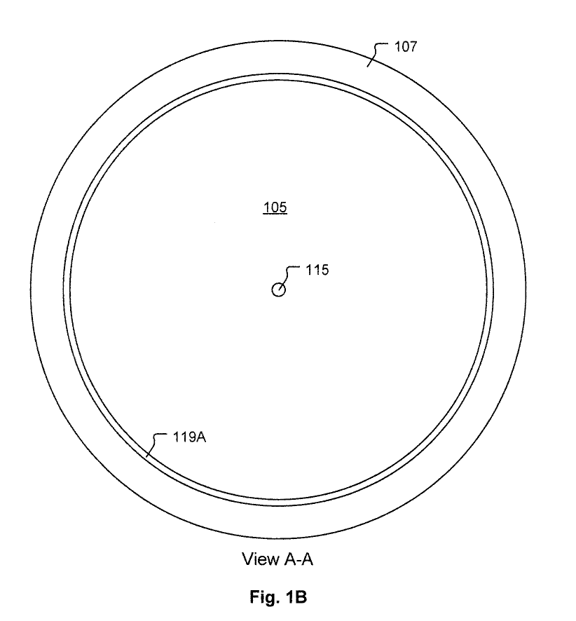

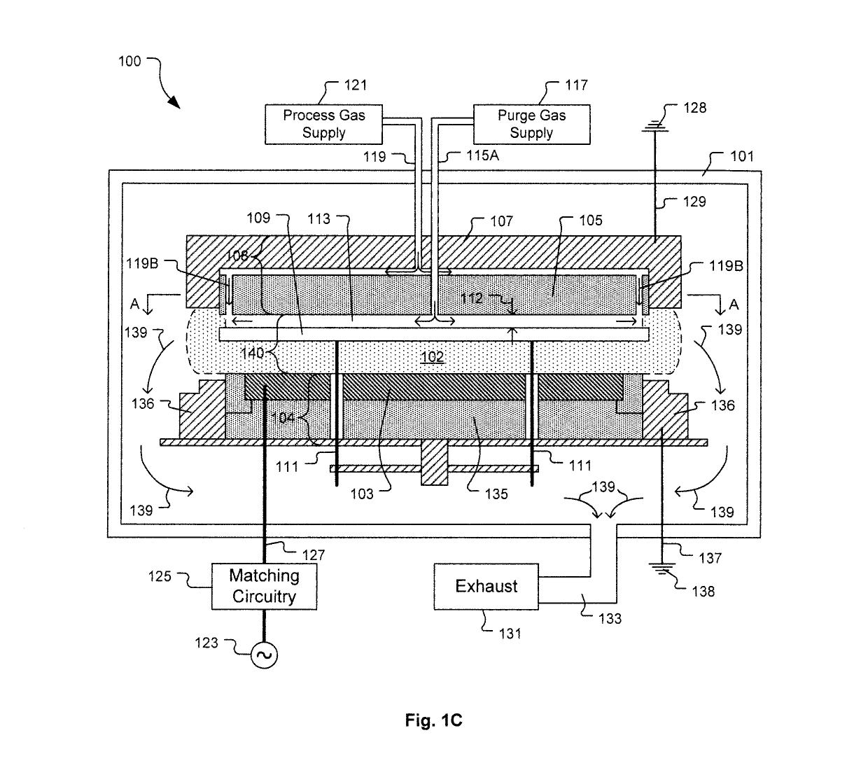

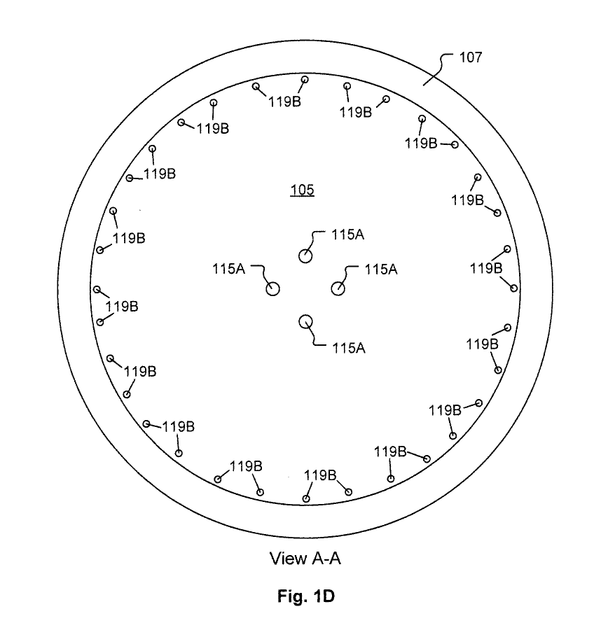

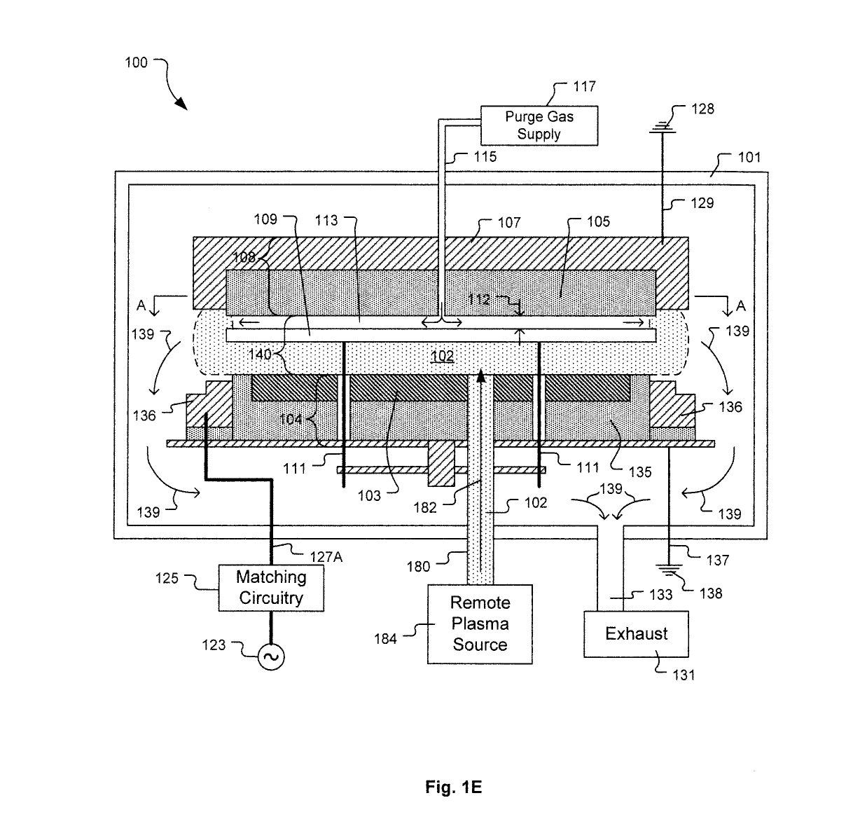

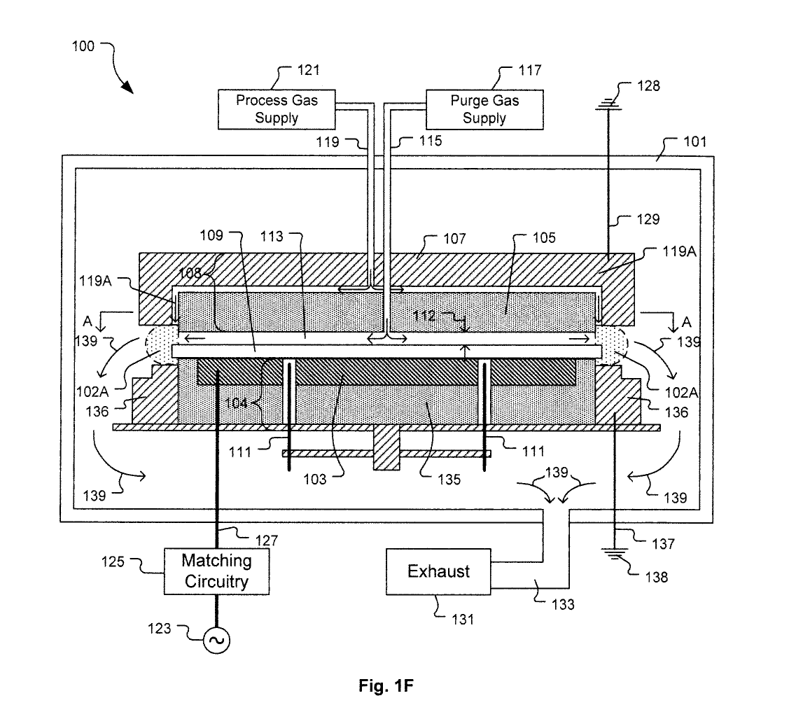

FIG. 1A shows a semiconductor processing system 100, in accordance with one embodiment of the present invention. The system includes a chamber 101. Within the chamber 101, a dielectric upper plate 105 is positioned parallel to and spaced apart from a lower electrode plate 103. An upper electrode plate 107 is positioned next to the dielectric upper plate 105, such that the dielectric upper plate 105 is located between the lower electrode plate 103 and the upper electrode plate 107. The upper electrode plate 107 is electrically connected to a reference ground potential 128, as indicated by electrical connection 129. The dielectric upper plate 105 and the upper electrode plate 107 together form an upper electrode assembly 108.

A radiofrequency (RF) power supply 123 is connected to supply RF power to the lower electrode plate 103, through matching circuitry 125, as indicated by electrical connection 127. It should be understood that the matching circuitry 125 is defined to control an electrical impedance through the electrical connection 127, such that the supplied RF power can be efficiently transmitted through the region 140. The lower electrode plate 103 is disposed within an inner base plate 135, which is held by an outer base plate 136. The outer base plate 136 is electrically connected to a reference ground potential 138, as indicated by electrical connection 137. The inner base plate 135 is formed of a dielectric material, so as to electrically separate the radiofrequency powered lower electrode plate 103 from the grounded outer base plate 136. The lower electrode plate 103, inner base plate 135, and outer base plate 136 together form a lower electrode assembly 104.

The upper electrode assembly 108 is separated from the lower electrode assembly 104 by a region 140 between an upper surface of the lower electrode plate 103 and a lower surface of the dielectric upper plate 105. A dielectric support is defined to support a workpiece 109 in an electrically isolated manner within the region 140 between the lower electrode plate 103 and the dielectric upper plate 105. In the embodiment of FIG. 1A, the dielectric support is defined as a set of dielectric lifting pins 111 that extend through the lower electrode plate 103 to support the workpiece 109 in an electrically isolated manner within the region 140 between the lower electrode plate 103 and the dielectric upper plate 105. In this configuration with the workpiece 109 supported on the set of dielectric lifting pins 111, the workpiece 109 is at a floating electrical potential. In one embodiment, the set of dielectric lifting pins 111 are formed of a ceramic material that is not electrically conductive.

The set of dielectric lifting pins 111 are defined to extend in a controllable manner into the region 140 between the lower electrode plate 103 and the dielectric upper plate 105 so as to control a distance 112 that forms a gap 113 between the top surface of the workpiece 109 and the dielectric upper plate 105 when the workpiece 109 is present on the set of dielectric lifting pins 111. In one embodiment, the distance 112 measured perpendicularly between the top surface of the workpiece 109 and the dielectric upper plate 105 is about 0.35 mm. However, it should be understood that in other embodiments, the distance 112 between the top surface of the workpiece 109 and the dielectric upper plate 105 can be set as needed. Also, it should be understood that the distance 112 between the top surface of the workpiece 109 and the dielectric upper plate 105 is adjustable during and/or between plasma processing operations.

In some embodiments, the dielectric upper plate 105 can include heating components to provide for temperature control of the workpiece 109. For example, in some embodiments, the dielectric upper plate 105 can include radiative heating elements to provide for radiative heating of the workpiece 109 across the gap 113. In other embodiments, the dielectric upper plate 105 can include resistive heaters to provide for heating of the dielectric upper plate 105 and in turn provide for radiative and/or convective heating of the workpiece 109.

A purge gas supply channel 115 is formed to supply a purge gas to the region 140 between the lower electrode plate 103 and the dielectric upper plate 105 at a central location of the dielectric upper plate 105. In one embodiment, such as shown in the example of FIG. 1A, the purge gas supply channel 115 is formed through both the upper electrode plate 107 and the dielectric upper plate 105, so as to dispense the purge gas at the central location of the dielectric upper plate 105 and at a substantially central location of the top surface of the workpiece 109 when present on the set of dielectric lifting pins 111. The purge gas supply channel 115 is fluidly connected to a purge gas supply 117 containing the purge gas.

During plasma processing operations, the purge gas flows radially outward through the gap 113 across the top surface of the workpiece 109 from the central location toward the periphery of the workpiece 109, so as to prevent reactive constituents of a plasma 102 from entering the gap 113 between the top surface of the workpiece 109 and the bottom surface of the dielectric upper plate 105 at the periphery of the top surface of the workpiece 109. Also, during plasma processing operations, the purge gas can provide for cooling of the workpiece 109. In some embodiments that utilize heating components within the dielectric upper plate 105, the cooling provided by the purge gas within the gap 113 combines with the heating provided by the heating components to provide an overall control of the workpiece 109 temperature. In various embodiments, the purge gas is defined as an inert gas such as nitrogen or helium, among others. However, it should be understood, that other gases or gas mixtures can be used for the purge gas in other embodiments, so long as the purge gas is chemically compatible with the plasma process and capable of providing both reactive plasma constituent exclusion from the region over the top surface of the workpiece 109 and required temperature control effects.

A process gas supply channel 119 is fluidly connected to a process gas supply 121 containing a process gas. The process gas is defined to transform into the plasma 102 when exposed to the RF power. The process gas supply channel 119 is formed to supply the process gas to locations near a periphery of the dielectric upper plate 105. The process gas emanating from the process gas supply channel 119 diffuses into the region 140 between the lower electrode plate 103 and the dielectric upper plate 105. In the example embodiment of FIG. 1A, the process gas supply channel 119 is formed through the upper electrode plate 107, and includes an open region 119A formed between the upper electrode plate 107 and dielectric upper plate 105.

In various embodiments, the process gas is defined as one or more of an oxygen based chemistry, a fluorine based chemistry, a chlorine based chemistry, among others. However, it should be understood, that other gases or gas mixtures can be used for the process gas in other embodiments, so long as the process gas is defined to transform into the plasma 102 having appropriate reactive constituent characteristics when exposed to the RF power supplied through the electrical connection 127. It should also be understood that in various embodiments the process gas can vary in composition depending on the characteristics of the RF power to be used, e.g., frequency, power, and duty cycle, the pressure to be applied inside the chamber 101, the temperature to be applied inside the chamber 101, the flow rate of the process gas through the chamber 101, and the types of reactive constituents needed to effect a particular reaction on the portions of the workpiece 109 in exposure to the plasma 102. In some embodiments, the RF power is supplied at a frequency of 60 megaHertz (MHz) or higher.

FIG. 1B shows a horizontal cross-sectional view A-A as denoted in FIG. 1A, in accordance with one embodiment of the present invention. As shown in FIG. 1B, the purge gas supply channel 115 is defined to dispense the purge gas at a substantially central location below the dielectric upper plate 105. Also, the open region between the upper electrode plate 107 and the dielectric upper plate 105 through which the process gas is dispensed is defined in a substantially uniform manner about a periphery of the dielectric upper plate 105, such that the process gas is dispensed in a substantially uniform manner about the periphery of the dielectric upper plate 105.

FIG. 1C shows a variation of the semiconductor processing system 100 in which the process gas supply channel 119 is defined to pass through the dielectric upper plate 105 a various locations about the periphery of the dielectric upper plate 105, as indicated by passages 119B, in accordance with one embodiment of the present invention. FIG. 1D shows the horizontal cross-sectional view A-A as denoted in FIG. 1C, in accordance with one embodiment of the present invention. As shown in FIG. 1D, the passages 119B through which the process gas flows are positioned in a substantially uniform manner about the periphery of the dielectric upper plate 105, such that the process gas is dispensed in a substantially uniform manner about the periphery of the dielectric upper plate 105. Also, it should be noted that FIG. 1D shows another embodiment in which the purge gas is supplied through multiple passages 115A to the location underlying the central region of the dielectric upper plate 105.

With reference back to FIG. 1A, during plasma processing operations within the semiconductor processing system 100, the purge gas is flowed through the purge gas supply channel 115 and the process gas is flowed through the process gas supply channel 119. The dielectric support defined as the set of dielectric lifting pins 111 is defined to position the workpiece 109 at a position proximate to and substantially parallel to the dielectric upper plate 105, such that the purge gas is made to flow from the purge gas supply channel 115 over a top surface of the workpiece 109 between the dielectric upper plate 105 and the top surface of the workpiece 109, so as to prevent the process gas from flowing over the top surface of the workpiece 109 and so as to cause the process gas to flow around the peripheral edge of the workpiece 109 and below the workpiece 109 into the region between the lower electrode plate 103 and the bottom surface of the workpiece 109, when the workpiece 109 is present on the set of dielectric lifting pins 111.

The purge gas outflow at the periphery of the dielectric upper plate 105 prevents the process gas and any reactive constituents of the plasma 102 from entering the region over the top surface of the workpiece 109. The process gas flows around and beneath the workpiece 109 and is transformed into the plasma 102 by the RF power transmitted through the electrical connection 127 to the lower electrode plate 103. The plasma 102 is exposed to the peripheral edge of the workpiece 109 and the bottom surface of the workpiece 109, so as to react with and remove unwanted materials from those regions of the workpiece 109. The process gas, purge gas, and plasma 102 reaction by-product materials are evacuated from the chamber 101 through a port 133 by way of an exhaust 131, as indicated by arrows 139.

It should be understood that any portion of the various components of the system 100 that are exposed to reactive constituents of the plasma 102 can be protected as necessary through use of plasma erosion resistant materials and/or through use of protective coatings, such as Y2O3 or other ceramic coatings. Also, in some embodiments, structures such as the lower electrode assembly 104 may be covered by a thin quartz plate, while ensuring that the RF power transfer from the lower electrode plate 103 to the plasma 102 is not disrupted by the thin quartz plate.

During plasma processing operations using the system 100, the etch rate of material from the bottom surface of the workpiece 109 is a partial function of the RF power applied to the process gas and the pressure of the process gas within the chamber 101. More specifically, a higher RF power yields a higher etch rate of material from the bottom surface of the workpiece 109, vice-versa. And, a lower pressure of the process gas within the chamber 101 yields a higher etch rate of material from the bottom surface of the workpiece 109, vice-versa. Additionally, uniformity of the material etch rate across the bottom surface of the workpiece 109 is improved at lower process gas pressure within the chamber 101.

In various embodiments, the RF power is supplied by the RF power supply 123 within a range extending from about 100 Watts (W) to about 10 kiloWatts (kW). In some embodiments, the RF power is supplied by the RF power supply 123 within a range extending from about 1 kW to about 3 kW. In some embodiments, the RF power is supplied by the RF power supply 123 within a frequency range extending from about 2 megaHertz (MHz) to about 60 MHz. In some embodiments, direct current (DC) power can also be applied to the lower electrode plate 103. Additionally, in some embodiments, multiple frequencies of RF power can be supplied to the lower electrode plate 103 at either the same time or at different times, such as in a cyclical manner.

In some embodiments, the pressure of the process gas within the chamber is controlled within a range extending from about 50 milliTorr (mT) to about 10 Torr (T). In some embodiments, the pressure of the process gas within the chamber is controlled within a range extending up to about 2 T. In some embodiments, the process gas is supplied to the plasma 102 generation volume at a flow rate within a range extending from about 0.1 standard liters per minute (slm) to about 5 slm. In some embodiments, the process gas is supplied to the plasma 102 generation volume at a flow rate within a range extending from about 1 slm to about 5 slm.

FIG. 1E shows a variation of the semiconductor processing system 100 of FIG. 1A defined to use a remote plasma source 184, in accordance with one embodiment of the present invention. The remote plasma source 184 is defined to generate reactive constituents of the plasma 102 external to the chamber 101, and flow the reactive constituents of the plasma 102 through a conduit 180 to the region beneath the workpiece 109, as indicated by arrow 182. Also in this embodiment, the RF power is supplied from the RF power supply 123 to the outer base plate 136, as indicated by electrical connection 127A, so as to generate more reactive constituents of the plasma 102 at the region near the peripheral edge of the workpiece 109. It should be understood that in this embodiment, the RF powered portions of the outer base plate 136 are electrically isolated from the reference ground potential 138.

In various embodiments, the RF power is supplied by the RF power supply 123 within a range extending from about 1 kW to about 10 kW. In some embodiments, the RF power is supplied by the RF power supply 123 within a range extending from about 5 kW to about 8 kW. In some embodiments, the RF power is supplied by the RF power supply 123 within a frequency range extending from about 2 MHz to about 60 MHz. In some embodiments, direct current (DC) power can also be applied to the lower electrode plate 104. Additionally, in some embodiments, multiple frequencies of RF power can be supplied to the outer base plate 136 at either the same time or at different times, such as in a cyclical manner.

Also, in this embodiment, it should be understood that the purge gas is made to flow from the purge gas supply channel 115 over the top surface of the workpiece 109 between the dielectric upper plate 105 and the top surface of the workpiece 109, so as to prevent the reactive constituents of the plasma 102 from flowing over and reacting with the top surface of the workpiece 109. The process gas, purge gas, and plasma 102 reaction by-product materials are evacuated from the chamber 101 through the port 133 by way of the exhaust 131, as indicated by arrows 139. In various embodiments, the remote plasma source 184 is defined to generate reactive constituents of the plasma 102 using RF power, microwave power, or a combination thereof. Also, in various embodiments, the remote plasma source 184 is defined as either a capacitive coupled plasma source or an inductively coupled plasma source.

In some embodiments, the pressure of a process gas within the remote plasma source 184 is controlled within a range extending from about 0.1 T to about 10 T. In some embodiments, the pressure of the process gas within the remote plasma source 184 is controlled within a range extending from about 1 T to about 10 T. In some embodiments, the process gas is supplied to the remote plasma source 184 at a flow rate within a range extending from about 0.1 slm to about 5 slm. In some embodiments, the process gas is supplied to the remote plasma source 184 at a flow rate within a range extending from about 1 slm to about 5 slm.

FIG. 1F shows the semiconductor processing system 100 in a configuration in which the workpiece 109 is lowered to rest on the lower electrode assembly 104 in order to perform plasma processing of the peripheral edge of the workpiece 109, in accordance with one embodiment of the present invention. In this embodiment, the purge gas is flowed through the purge gas supply channel 115 and the process gas is flowed through the process gas supply channel 119. The set of dielectric lifting pins 111 are fully retracted such that the workpiece 109 rests on the lower electrode assembly 104 at a position proximate to and substantially parallel to the dielectric upper plate 105, such that the purge gas is made to flow from the purge gas supply channel 115 over a top surface of the workpiece 109 between the dielectric upper plate 105 and the top surface of the workpiece 109, so as to prevent the process gas from flowing over the top surface of the workpiece 109 and so as to cause the process gas to flow around the peripheral edge of the workpiece 109.

The purge gas outflow at the periphery of the dielectric upper plate 105 prevents the process gas and any reactive constituents of the plasma 102A from entering the region over the top surface of the workpiece 109. The process gas flows around the peripheral edge of the workpiece 109 and is transformed into the plasma 102A by the RF power transmitted through the electrical connection 127 to the lower electrode plate 103. The plasma 102A is exposed to the peripheral edge of the workpiece 109, so as to react with and remove unwanted materials from those regions of the workpiece 109. The process gas, purge gas, and plasma 102A reaction by-product materials are evacuated from the chamber 101 through the port 133 by way of the exhaust 131, as indicated by arrows 139.

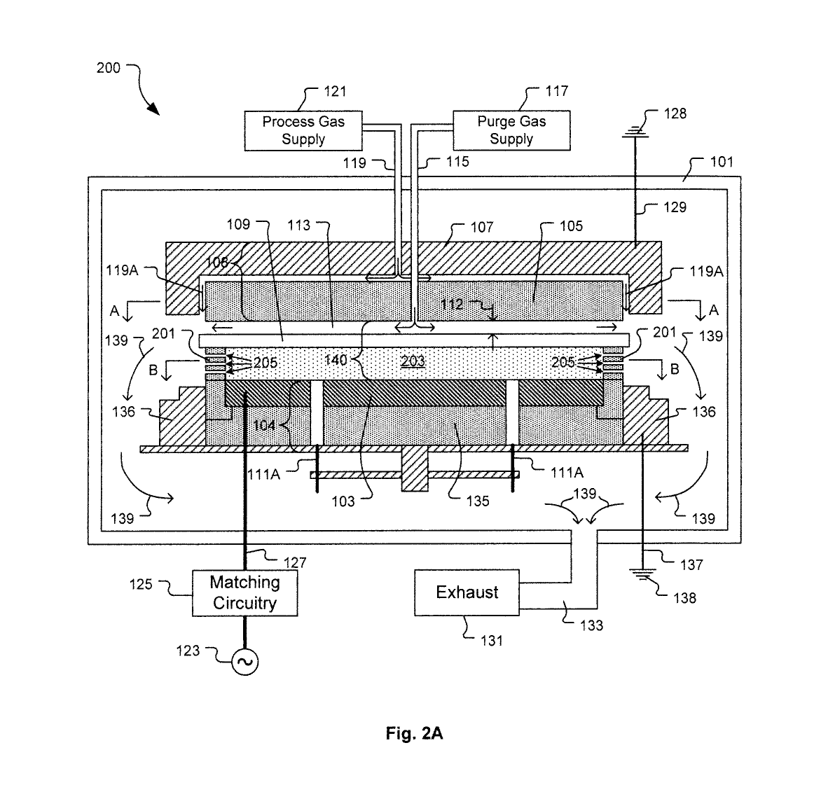

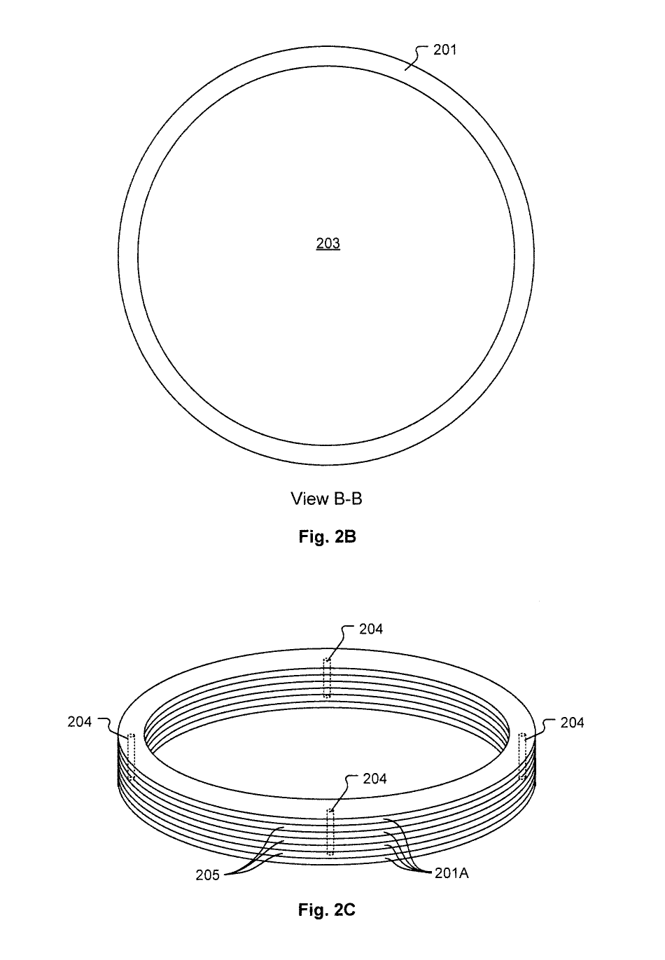

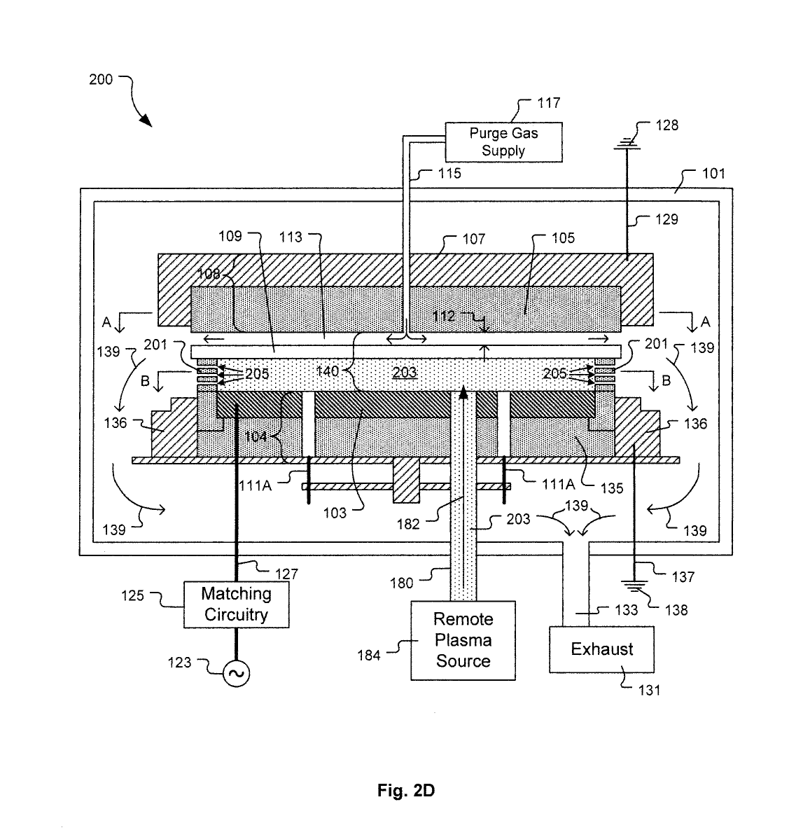

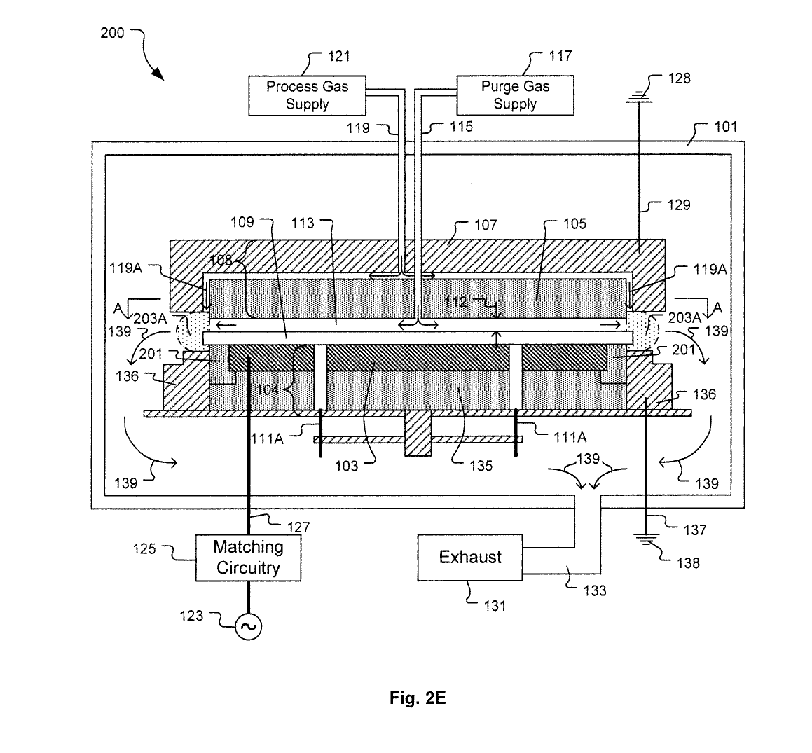

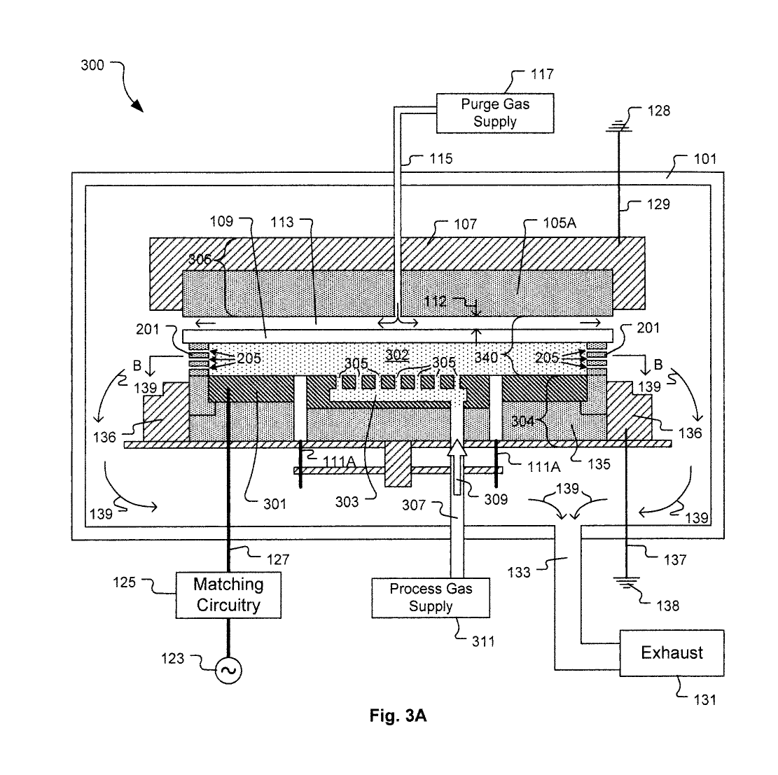

FIG. 2A shows a semiconductor processing system 200, in accordance with one embodiment of the present invention. As with the system 100 of FIG. 1A, the system 200 includes the chamber 101, the upper electrode assembly 108, and the lower electrode assembly 104. The upper electrode assembly 108 includes the dielectric upper plate 105 and the upper electrode plate 107. The upper electrode plate 107 is electrically connected to the reference ground potential 128, as indicated by the electrical connection 129. The purge gas supply channel 115 extends from the purge gas supply 117 through the upper electrode assembly 108 to provide for supply of the purge gas at the central location below the dielectric upper plate 105. The process gas supply channel 119 extends from the process gas supply 121 through the upper electrode assembly 108 to provide for supply of the process gas at the outer peripheral edge of the workpiece 109.

The lower electrode assembly 104 includes the lower electrode plate 103 supported by the inner base plate 135, which is supported by the outer base plate 136. The lower electrode plate 103 is electrically connected to receive RF power from the RF power supply 123 by way of the matching circuitry 125 and electrical connection 127. The outer base plate 136 is formed of an electrically conductive material and is electrically connected to the reference ground potential 137. The inner base plate 135 is formed of a dielectric material so as to electrically isolate the RF powered lower electrode plate 103 from the grounded outer base plate 136.

The system 200 can also include a set of lifting pins 111A for handling of the workpiece 109 during placement of the workpiece 109 within the chamber 101 and removal of the workpiece from the chamber 101. However, unlike the set of dielectric lifting pins 111 in the system 100, the set of lifting pins 111A in the system 200 are not used as the dielectric support to support the workpiece 109 during plasma processing operations within the chamber 101. Instead, the system 200 includes a dielectric edge ring 201 to serve as the dielectric support for the workpiece 109. The dielectric edge ring 201 is formed of a dielectric material and has an annular shape with an upper surface defined to contact and support a peripheral region of the bottom surface of the workpiece 109.

FIG. 2B shows the horizontal cross-sectional view B-B as denoted in FIG. 2A, in accordance with one embodiment of the present invention. As shown in FIG. 2B, the dielectric edge ring 201 has an annular shape so as to confine a plasma 203 to be generated within the region between the top surface of the lower electrode plate 103 and the bottom surface of the workpiece 109. In this manner, the dielectric edge ring 201 is defined as a plasma exclusion zone (PEZ) ring.

With reference back to FIG. 2A, the dielectric edge ring 201 is defined to extend in a controllable manner into the region 140 between the lower electrode plate 103 and the dielectric upper plate 105 so as to control the distance 112 between the top surface of the workpiece 109 and the dielectric upper plate 105 when the workpiece 109 is present on the dielectric edge ring 201. Extension of the dielectric edge ring 201 into the region 140 between the lower electrode plate 103 and the dielectric upper plate 105 also forms a plasma generation volume beneath the workpiece 109 and above the lower electrode plate 103, such that the bottom surface of the workpiece 109 can be exposed to a plasma 203 generated with the plasma generation volume. Thus, the dielectric edge ring 201 also functions to confine the plasma 203 to the plasma generation volume beneath the workpiece 109. It should be understood that in some embodiments, the position of the dielectric edge ring 201 relative to the lower electrode plate 103 is adjustable, thereby providing for adjustment of the size of the plasma processing volume between the workpiece 109 and the lower electrode plate 103.

The dielectric edge ring 201 includes vents 205 defined to allow for flow of the process gas from an output of the process gas supply channel 119 to the region between the lower electrode plate 103 and the bottom surface of the workpiece 109, when the workpiece 109 is present on the dielectric edge ring 201. FIG. 2C shows an example embodiment in which the dielectric edge ring 201 is defined as a stack of annular shaped rings 201A separated from each other by spaces that form the vents 205. In this embodiment, the annular shaped rings 201A can be held in their spaced apart relationship by structural members 204 that connect to the various annular shaped rings 201A at a number of locations around the circumference of the annular shaped rings 201A. Also, in some embodiments, these structural members 204 can be defined to hold the annular shaped rings 201A in a fixed spatial configuration. And, in some embodiments, these structural members 204 can be defined to provide for controlled variation of the spatial configuration of the annular shaped rings 201A relative to each other, such that the spacing between the various annular shaped rings 201A that form the vents 205 can be adjusted in size.

It should be understood that the dielectric edge ring 201 embodiment of FIG. 2C is one of many possible dielectric edge region 201 embodiments. For example, in other embodiments, the dielectric edge ring 201 may be a single monolithic structure that includes radially oriented passages for venting gases from the plasma processing volume beneath the workpiece 109. Regardless of the particular embodiment, however, it should be understood that the dielectric edge ring 201 is formed of a dielectric material, has a top surface defined to support the workpiece 109 at the radial periphery of the bottom surface of the workpiece 109, and includes through-holes, vents, or other types of passages such that dielectric edge ring 201 serves as baffle for process gases and plasma process by-product materials exiting from the plasma processing volume beneath the workpiece 109.

During the supply of the process gas through the process gas supply channel 119, the exhaust 131 can be turned off such that the process gas will diffuse through the vents 205 of the dielectric edge ring 201 into the plasma generation volume below the workpiece 109. Then, the purge gas can be supplied through the purge gas supply channel 115 to purge the gap 113 above the workpiece 109 of process gas. RF power can be supplied from the RF power supply 123 to the lower electrode plate 103, by way of the matching circuitry 125 and electrical connection 127, to transform the process gas within the plasma generation volume beneath the workpiece 109 into the plasma 203, whereby reactive constituents of the plasma 203 interact with the bottom surface of the workpiece 109 to remove undesirable materials from the workpiece 109. Then, the exhaust 131 can be turned on to evacuate both purge gases and process gases from within the chamber 101, and to evacuate the process gases and plasma processing by-product materials from the plasma generation volume beneath the workpiece 109, through the vents 205 of the dielectric edge ring 201 to the exhaust port 133, as indicated by arrows 139. Additionally, in some embodiments, the exhaust 131 may be turned on during supply of the RF power to generate the plasma 203, thereby providing for evacuation of process gases, purge gases, and plasma processing by-product materials during the plasma processing operation.

It should be understood that any portion of the various components of the system 200 that are exposed to reactive constituents of the plasma 203 can be protected as necessary through use of plasma erosion resistant materials and/or through use of protective coatings, such as Y2O3 or other ceramic coatings. Also, in some embodiments, structures such as the lower electrode assembly 104 may be covered by a thin quartz plate, while ensuring that the RF power transfer from the lower electrode plate 103 to the plasma 203 is not disrupted by the thin quartz plate.

During plasma processing operations using the system 200, the etch rate of material from the bottom surface of the workpiece 109 is a partial function of the RF power applied to the process gas and the pressure of the process gas within the chamber 101. More specifically, a higher RF power yields a higher etch rate of material from the bottom surface of the workpiece 109, vice-versa. And, a lower pressure of the process gas within the chamber 101 yields a higher etch rate of material from the bottom surface of the workpiece 109, vice-versa. Additionally, uniformity of the material etch rate across the bottom surface of the workpiece 109 is improved at lower process gas pressure within the chamber 101.

In various embodiments, the RF power is supplied by the RF power supply 123 within a range extending from about 100 W to about 10 kW. In some embodiments, the RF power is supplied by the RF power supply 123 within a range extending from about 1 kW to about 3 kW. In some embodiments, the RF power is supplied by the RF power supply 123 within a frequency range extending from about 2 MHz to about 60 MHz. In some embodiments, direct current (DC) power can also be applied to the lower electrode plate 103. Additionally, in some embodiments, multiple frequencies of RF power can be supplied to the lower electrode plate 103 at either the same time or at different times, such as in a cyclical manner.

In some embodiments, the pressure of the process gas within the chamber is controlled within a range extending from about 50 mT to about 10 T. In some embodiments, the pressure of the process gas within the chamber is controlled within a range extending up to about 2 T. In some embodiments, the process gas is supplied to the plasma 102 generation volume at a flow rate within a range extending from about 0.1 slm to about 5 slm. In some embodiments, the process gas is supplied to the plasma 102 generation volume at a flow rate within a range extending from about 1 slm to about 5 slm.

FIG. 2D shows a variation of the semiconductor processing system 200 of FIG. 2A defined to use a remote plasma source 184, in accordance with one embodiment of the present invention. The remote plasma source 184 is defined to generate reactive constituents of the plasma 203 external to the chamber 101, and flow the reactive constituents of the plasma 203 through a conduit 180 to the region beneath the workpiece 109, as indicated by arrow 182.

The process gas, purge gas, and plasma 203 reaction by-product materials are evacuated from the chamber 101 through the port 133 by way of the exhaust 131, as indicated by arrows 139. In various embodiments, the remote plasma source 184 is defined to generate reactive constituents of the plasma 203 using RF power, microwave power, or a combination thereof. Also, in various embodiments, the remote plasma source 184 is defined as either a capacitively coupled plasma source or an inductively coupled plasma source.

In some embodiments, the pressure of a process gas within the remote plasma source 184 is controlled within a range extending from about 0.1 T to about 10 T. In some embodiments, the pressure of the process gas within the remote plasma source 184 is controlled within a range extending from about 1 T to about 10 T. In some embodiments, the process gas is supplied to the remote plasma source 184 at a flow rate within a range extending from about 0.1 slm to about 5 slm. In some embodiments, the process gas is supplied to the remote plasma source 184 at a flow rate within a range extending from about 1 slm to about 5 slm.

FIG. 2E shows the semiconductor processing system 200 in a configuration in which the workpiece 109 is lowered to rest on the lower electrode assembly 104 in order to perform plasma processing of the peripheral edge of the workpiece 109, in accordance with one embodiment of the present invention. In this embodiment, the purge gas is flowed through the purge gas supply channel 115 and the process gas is flowed through the process gas supply channel 119. The dielectric edge ring 201 is fully retracted such that the workpiece 109 rests on the lower electrode assembly 104 at a position proximate to and substantially parallel to the dielectric upper plate 105, such that the purge gas is made to flow from the purge gas supply channel 115 over a top surface of the workpiece 109 between the dielectric upper plate 105 and the top surface of the workpiece 109, so as to prevent the process gas from flowing over the top surface of the workpiece 109 and so as to cause the process gas to flow around the peripheral edge of the workpiece 109.

The purge gas outflow at the periphery of the dielectric upper plate 105 prevents the process gas and any reactive constituents of the plasma 203A from entering the region over the top surface of the workpiece 109. The process gas flows around the peripheral edge of the workpiece 109 and is transformed into the plasma 203A by the RF power transmitted through the electrical connection 127 to the lower electrode plate 103. The plasma 203A is exposed to the peripheral edge of the workpiece 109, so as to react with and remove unwanted materials from those regions of the workpiece 109. The process gas, purge gas, and plasma 203A reaction by-product materials are evacuated from the chamber 101 through the port 133 by way of the exhaust 131, as indicated by arrows 139.

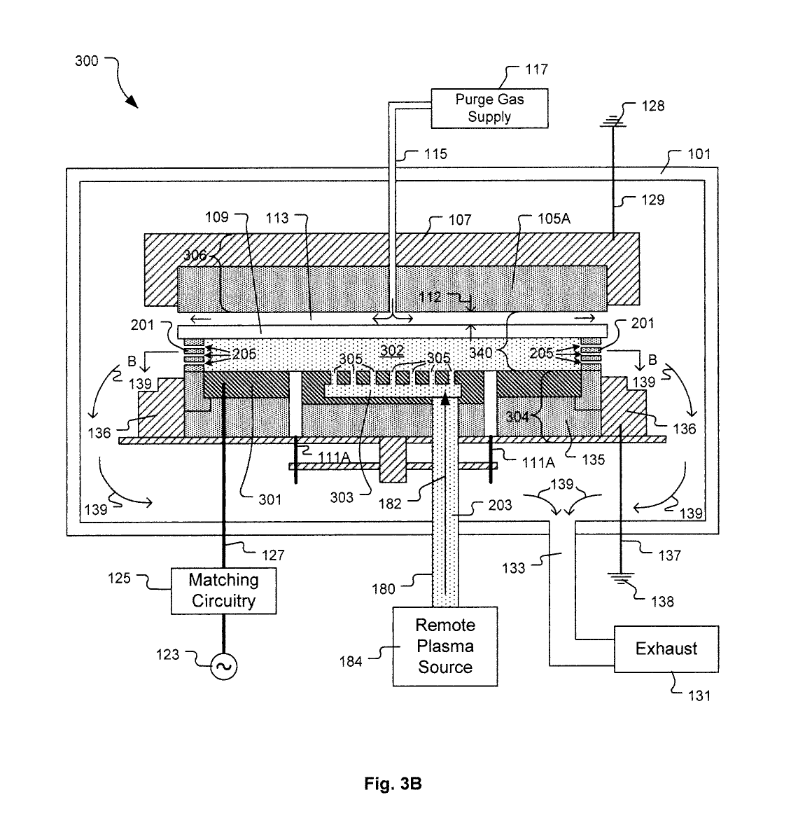

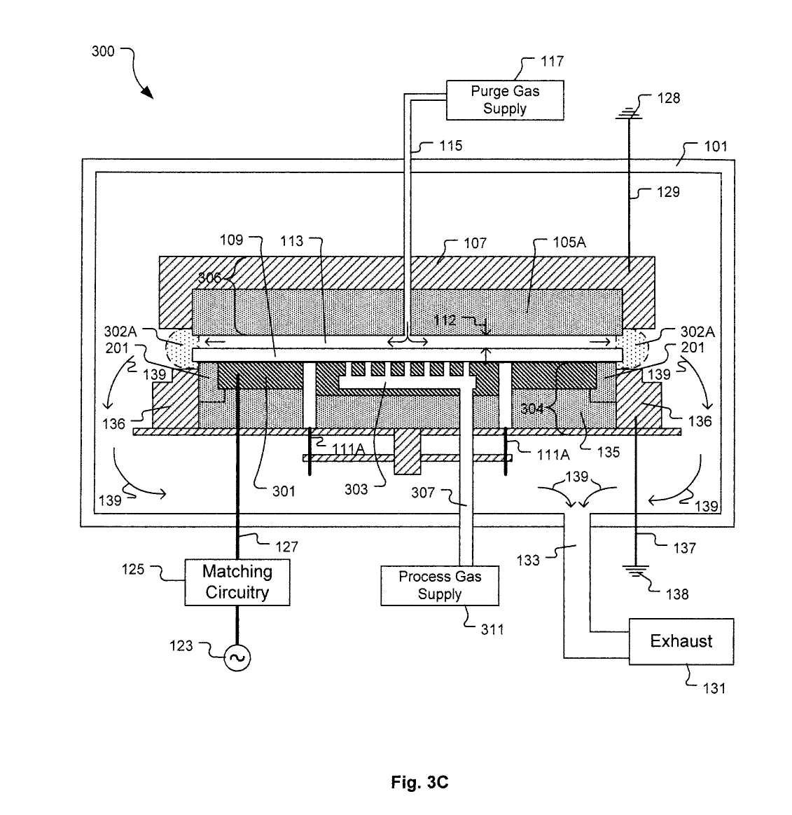

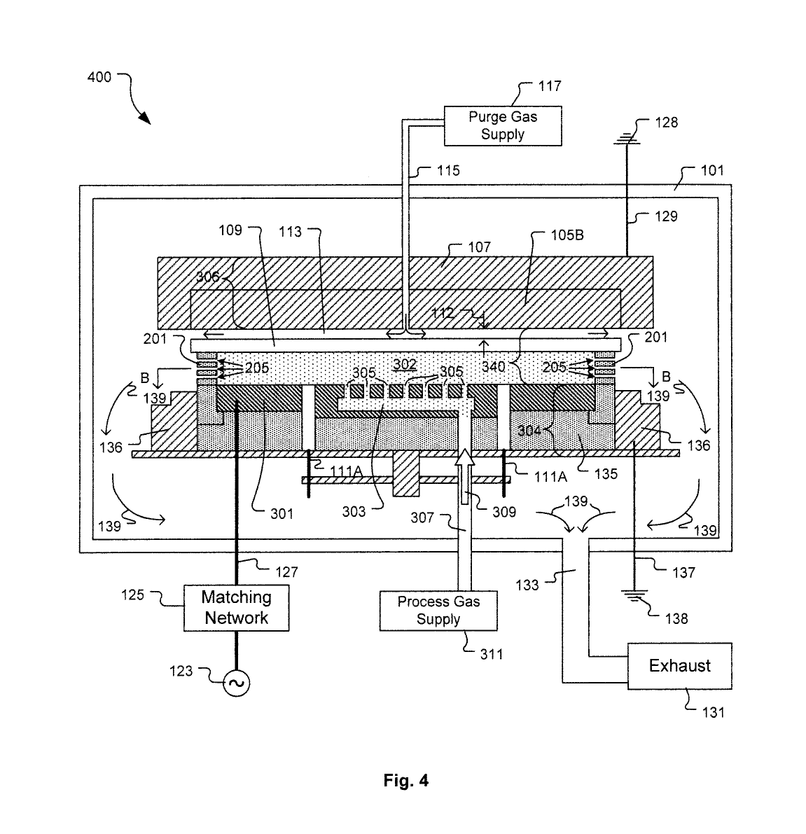

FIG. 3A shows a semiconductor processing system 300, in accordance with one embodiment of the present invention. The system 300 includes the chamber 101 and an upper electrode assembly 306, which includes a dielectric upper plate 105A and the upper electrode plate 107. The upper electrode plate 107 is electrically connected to the reference ground potential 128, as indicated by the electrical connection 129. The purge gas supply channel 115 extends from the purge gas supply 117 through the upper electrode assembly 306 to provide for supply of the purge gas at the central location below the dielectric upper plate 105A.

The system 300 also includes a lower electrode assembly 304 that includes a lower showerhead electrode plate 301 having an interior region 303 for transforming a process gas into a plasma 302. The lower showerhead electrode plate 301 includes a number of vents 305 extending from an upper surface of the lower showerhead plate 301 to the interior region 303. The lower showerhead electrode plate 301 is supported by the inner base plate 135, which is supported by the outer base plate 136. The lower showerhead electrode plate 301 is electrically connected to receive RF power from the RF power supply 123 by way of the matching circuitry 125 and electrical connection 127. The outer base plate 136 is formed of an electrically conductive material and is electrically connected to the reference ground potential 137. The inner base plate 135 is formed of a dielectric material so as to electrically isolate the RF powered lower showerhead electrode plate 301 from the grounded outer base plate 136. It should be appreciated that the lower showerhead electrode plate 301 serves as both a process gas distribution plate and an RF transmission electrode.

A process gas supply channel 307 is formed through the lower electrode assembly 304 to supply a process gas from a process gas supply 311 to the interior region 303 of the lower showerhead electrode plate 301, as indicated by arrow 309. The RF power supplied to the lower showerhead electrode plate 301 serves to transform the process gas into the plasma 302 within the interior region 303 of the lower showerhead electrode plate 301.

In view of the foregoing, the dielectric upper plate 105A represents a first upper plate positioned parallel to and spaced apart from the lower showerhead electrode plate 301, where the first upper plate is formed of a dielectric material. And, the upper electrode plate 107 represents a second upper plate positioned next to the first upper plate such that the first upper plate is located between the lower showerhead electrode plate 301 and the second upper plate, where the second upper plate electrically connected to the reference ground potential 128.

The system 300 can also include a set of lifting pins 111A for handling of the workpiece 109 during placement of the workpiece 109 within the chamber 101 and removal of the workpiece 109 from the chamber 101. However, unlike the set of dielectric lifting pins 111 in the system 100, the set of lifting pins 111A in the system 300 are not used as the dielectric support to support the workpiece 109 during plasma processing operations within the chamber 101. Instead, like the system 200, the system 300 includes the dielectric edge ring 201 to serve as the dielectric support for the workpiece 109.

As discussed above, the dielectric edge ring 201 is formed of a dielectric material and has an annular shape with an upper surface defined to contact and support a peripheral region of the bottom surface of the workpiece 109, and support the workpiece 109 in an electrically isolated manner within a region 340 between the upper surface of the lower showerhead electrode plate 301 and a lower surface of the dielectric upper plate 105A, i.e., of the first upper plate. Also, as previously discussed, the dielectric edge ring 201 includes vents 205 defined to allow for flow of process gases and plasma process by-product materials from the region below the workpiece 109. It should be understood that the dielectric edge ring 201 is formed of a dielectric material, has a top surface defined to support the workpiece 109 at the radial periphery of the bottom surface of the workpiece 109, and includes through-holes, vents, or other types of passages such that dielectric edge ring 201 serves as baffle for process gases and plasma process by-product materials exiting from the region beneath the workpiece 109.

In the system 300, the dielectric edge ring 201 is defined to extend in a controllable manner into the region 340 between the lower showerhead electrode plate 301 and the dielectric upper plate 105A so as to control the distance 112 between the top surface of the workpiece 109 and the dielectric upper plate 105A when the workpiece 109 is present on the dielectric edge ring 201. The dielectric edge ring 201 is defined to position the workpiece 109 proximate to and substantially parallel to the dielectric upper plate 105A (the first upper plate) such that the purge gas is made to flow from the purge gas supply channel 115 over a top surface of the workpiece 109 through the gap 113 between the lower surface of the dielectric upper plate 105A (first upper plate) and the top surface of the workpiece 109, so as to prevent reactive constituents of the plasma 302 from reaching the top surface of the workpiece 109, when the workpiece 109 is present on the dielectric edge ring 201.

Extension of the dielectric edge ring 201 into the region 340 between the lower showerhead electrode plate 301 and the dielectric upper plate 105A also forms a plasma generation volume beneath the workpiece 109 and above the lower showerhead electrode plate 301, such that the bottom surface of the workpiece 109 can be exposed to the plasma 302 generated with the plasma generation volume. Thus, the dielectric edge ring 201 also functions to confine the plasma 302 to the plasma generation volume beneath the workpiece 109. It should be understood that in some embodiments, the position of the dielectric edge ring 201 relative to the lower showerhead electrode plate 301 is adjustable, thereby providing for adjustment of the size of the plasma processing volume between the workpiece 109 and the lower showerhead electrode plate 301.

During operation of the system 300 to perform plasma processing operations, the purge gas is supplied from the purge gas supply 117 through the purge gas supply channel 115 to flow over the top surface of the workpiece 109 and thereby prevent reactive constituents of the plasma 302 from reaching the top surface of the workpiece 109. Also, the process gas is supplied from the process gas supply 311 through the process gas supply channel 307 to the interior region 303 of the lower showerhead electrode plate 301, while RF power is supplied to the lower showerhead electrode plate 301 from the RF power supply 123 by way of the matching circuitry 125 and electrical connection 127. The RF power transforms the process gas within the interior region 303 of the lower showerhead electrode plate 301 into the plasma 302, whereby reactive constituents of the plasma 302 interact with the bottom surface of the workpiece 109 to remove undesirable materials from the workpiece 109. The exhaust 131 is operated to evacuate both purge gases and process gases from within the chamber 101, and to evacuate the process gases and plasma processing by-product materials from the plasma generation volume beneath the workpiece 109, through the vents 205 of the dielectric edge ring 201 to the exhaust port 133, as indicated by arrows 139.

It should be understood that any portion of the various components of the system 300 that are exposed to reactive constituents of the plasma 302 can be protected as necessary through use of plasma erosion resistant materials and/or through use of protective coatings, such as Y2O3 or other ceramic coatings. Also, in some embodiments, structures such as the lower showerhead electrode plate 301 may be covered by a thin quartz plate.

During plasma processing operations using the system 300, the etch rate of material from the bottom surface of the workpiece 109 is a partial function of the RF power applied to the process gas and the pressure of the process gas within the chamber 101. More specifically, a higher RF power yields a higher etch rate of material from the bottom surface of the workpiece 109, vice-versa. And, a lower pressure of the process gas within the chamber 101 yields a higher etch rate of material from the bottom surface of the workpiece 109, vice-versa. Additionally, uniformity of the material etch rate across the bottom surface of the workpiece 109 is improved at lower process gas pressure within the chamber 101.

In various embodiments, the RF power is supplied by the RF power supply 123 within a range extending from about 100 W to about 10 kW. In some embodiments, the RF power is supplied by the RF power supply 123 within a range extending from about 1 kW to about 3 kW. In some embodiments, the RF power is supplied by the RF power supply 123 within a frequency range extending from about 2 MHz to about 60 MHz. In some embodiments, direct current (DC) power can also be applied to the lower electrode plate 103. Additionally, in some embodiments, multiple frequencies of RF power can be supplied to the lower electrode plate 103 at either the same time or at different times, such as in a cyclical manner.

In some embodiments, the pressure of the process gas within the chamber is controlled within a range extending from about 50 mT to about 10 T. In some embodiments, the pressure of the process gas within the chamber is controlled within a range extending up to about 2 T. In some embodiments, the process gas is supplied to the plasma 102 generation volume at a flow rate within a range extending from about 0.1 slm to about 5 slm. In some embodiments, the process gas is supplied to the plasma 102 generation volume at a flow rate within a range extending from about 1 slm to about 5 slm.

FIG. 3B shows a variation of the semiconductor processing system 300 of FIG. 3A defined to use a remote plasma source 184, in accordance with one embodiment of the present invention. The remote plasma source 184 is defined to generate reactive constituents of the plasma 302 external to the chamber 101, and flow the reactive constituents of the plasma 302 through a conduit 180 to the interior region 303 of the lower showerhead electrode plate 301, as indicated by arrow 182, and ultimately to the region beneath the workpiece 109.

The process gas, purge gas, and plasma 302 reaction by-product materials are evacuated from the chamber 101 through the port 133 by way of the exhaust 131, as indicated by arrows 139. In various embodiments, the remote plasma source 184 is defined to generate reactive constituents of the plasma 302 using RF power, microwave power, or a combination thereof. Also, in various embodiments, the remote plasma source 184 is defined as either a capacitively coupled plasma source or an inductively coupled plasma source.

In various embodiments, RF power within a range extending from about 1 kW to about 10 kW is used to generate the plasma 302 in the remote plasma source 184. In some embodiments, RF power within a range extending from about 5 kW to about 8 kW is used to generate the plasma 302 in the remote plasma source 184. In some embodiments, RF power within a frequency range extending from about 2 MHz to about 60 MHz is used to generate the plasma 302 in the remote plasma source 184. In some embodiments, direct current (DC) power can also be applied to the lower showerhead electrode plate 301. Additionally, in some embodiments, multiple frequencies of RF power can be used to generate the plasma 302 within the remote plasma source 184 at either the same time or at different times, such as in a cyclical manner.

In some embodiments, the pressure of a process gas within the remote plasma source 184 is controlled within a range extending from about 0.1 T to about 10 T. In some embodiments, the pressure of the process gas within the remote plasma source 184 is controlled within a range extending from about 1 T to about 10 T. In some embodiments, the process gas is supplied to the remote plasma source 184 at a flow rate within a range extending from about 0.1 slm to about 5 slm. In some embodiments, the process gas is supplied to the remote plasma source 184 at a flow rate within a range extending from about 1 slm to about 5 slm.

FIG. 3C shows the semiconductor processing system 300 in a configuration in which the workpiece 109 is lowered to rest on the lower electrode assembly 304 in order to perform plasma processing of the peripheral edge of the workpiece 109, in accordance with one embodiment of the present invention. In this embodiment, the purge gas is flowed through the purge gas supply channel 115 and the process gas is flowed through the process gas supply channel 119. The dielectric edge ring 201 is fully retracted such that the workpiece 109 rests on the lower electrode assembly 304 at a position proximate to and substantially parallel to the dielectric upper plate 105A, such that the purge gas is made to flow from the purge gas supply channel 115 over a top surface of the workpiece 109 between the dielectric upper plate 105 and the top surface of the workpiece 109, so as to prevent the process gas from flowing over the top surface of the workpiece 109 and so as to cause the process gas to flow around the peripheral edge of the workpiece 109.

The purge gas outflow at the periphery of the dielectric upper plate 105 prevents the process gas and any reactive constituents of the plasma 302A from entering the region over the top surface of the workpiece 109. The process gas flows around the peripheral edge of the workpiece 109 and is transformed into the plasma 302A by the RF power transmitted through the electrical connection 127 to the lower showerhead electrode plate 301. The plasma 302A is exposed to the peripheral edge of the workpiece 109, so as to react with and remove unwanted materials from those regions of the workpiece 109. The process gas, purge gas, and plasma 302A reaction by-product materials are evacuated from the chamber 101 through the port 133 by way of the exhaust 131, as indicated by arrows 139.

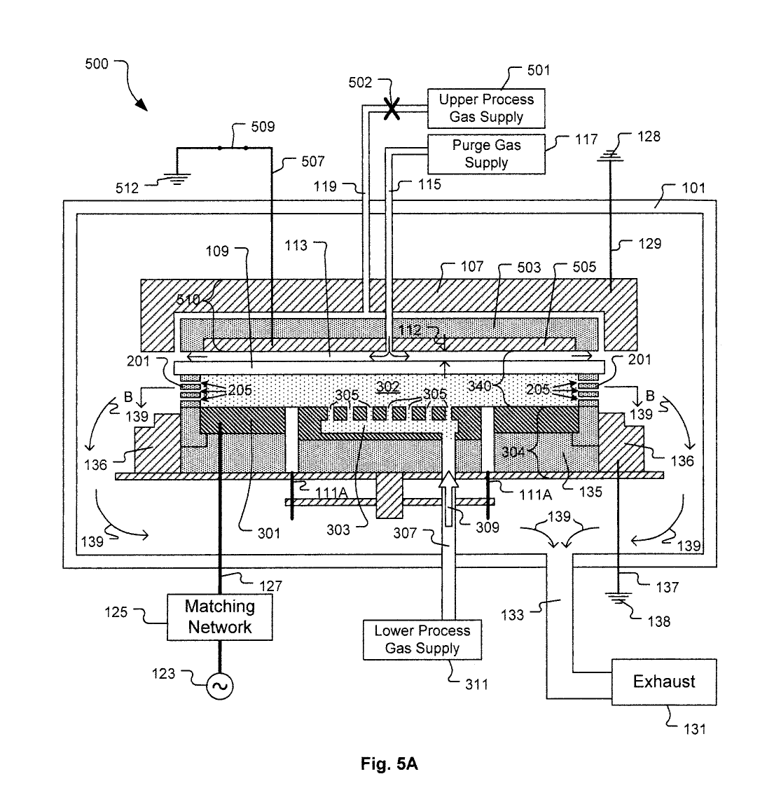

FIG. 4 shows a semiconductor processing system 400 that is a variation of the system 300 described with regard to FIG. 3A, in accordance with one embodiment of the present invention. Specifically, the system 400 of FIG. 4 is the same as the system 300 of FIG. 3A, with the exception that the dielectric upper plate 105A is replaced by a conductive upper plate 105B formed of an electrically conductive material. All other features of the system 400 of FIG. 4 are the same as discussed above with regard to the system 300 of FIG. 3A. The conductive upper plate 105B is electrically connected to the reference ground potential 128. Therefore, in the system 400, the workpiece 109 is capacitively coupled to the reference ground potential by way of its close proximity to the conductive upper plate 105B.

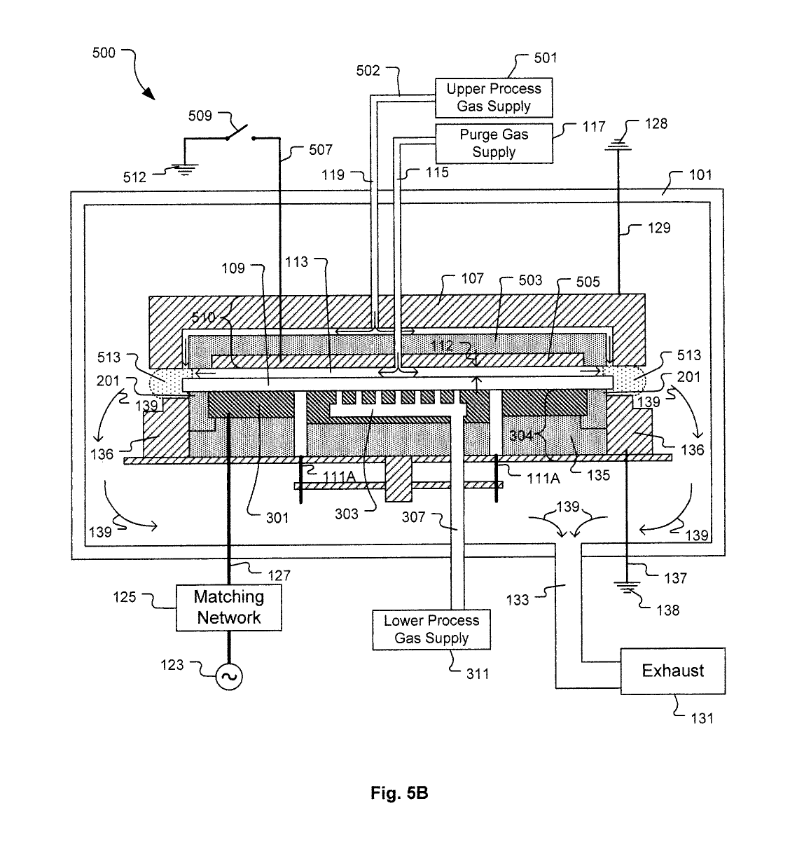

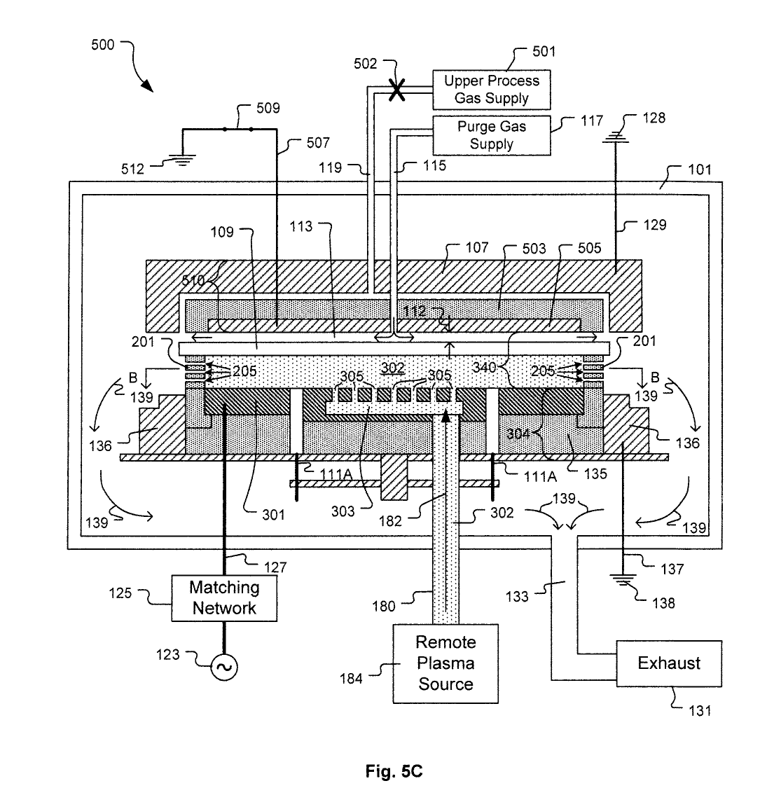

FIGS. 5A and 5B show a semiconductor processing system 500 that is also a variation of the system 300 described with regard to FIG. 3A, in accordance with one embodiment of the present invention. Specifically, the system 500 of FIGS. 5A and 5B is the same as the system 300 of FIG. 3A, with the exceptions that the upper electrode assembly 306 is replaced by a configurable upper electrode assembly 510, and that an upper process gas supply 501 is provided. Other features of the system 500 of FIGS. 5A and 5B are the same as discussed above with regard to the system 300 of FIG. 3A.

In the system 500, the configurable upper electrode assembly 510 includes an electrically conductive interior electrode plate 505, a dielectric member 503, and the upper electrode plate 107. The dielectric member 503 serves to electrically isolate the electrically conductive interior electrode plate 505 from the upper electrode plate 107. The upper electrode plate 107 is electrically connected to the reference ground potential 128 by way of the electrical connection 129. The electrically conductive interior electrode plate 505 is electrically connected to a switch 509 by way of an electrical connection 507, and the switch 509 is in turn electrically connected to a reference ground potential 512. In this manner, the switch 509 provides for control of electrical connection of the electrically conductive interior electrode plate 505 to the reference ground potential 512.

Also, the system 500 includes the process gas supply channel 119 formed through the configurable upper electrode assembly 510, similar to the process gas supply channel 119 formed through the upper electrode assembly 108 as discussed with regard to the system 100 of FIG. 1A. The process gas supply channel 119 is fluidly connected to an upper process gas supply 501 containing a process gas. The process gas is defined to transform into the plasma 302 when exposed to the RF power. The process gas supply channel 119 is formed to supply the process gas to locations near a periphery of the workpiece 109 when present on the dielectric edge ring 201. A valve 502 is provided to control the flow of process gas through the process gas supply channel 119, such that the flow of process gas from the upper process gas supply 501 can be turned off when performing the backside plasma cleaning of the workpiece 109 and turned on when performing the bevel edge plasma cleaning of the workpiece 109.

FIG. 5A shows the system 500 in a configuration for performing the backside plasma cleaning of the workpiece 109. In this configuration, the dielectric edge ring 201 is raised to create the plasma processing volume beneath the workpiece 109, and the process gas is supplied from the lower process gas supply 311 to the interior region 303 of the lower showerhead electrode plate 301 to generate the plasma 302 beneath the workpiece 109. Also, in this configuration, the valve 502 is closed so as to turn off the flow of process gas from the upper process gas supply 501. In this configuration, the purge gas is supplied from the purge gas supply 117 to the gap 113 between the configurable upper electrode assembly 510 and the workpiece 109, so as to prevent reactive constituents of the plasma 302 from reaching the top surface of the workpiece 109. Also, in this configuration, the switch 509 is set to electrically connect the electrically conductive interior electrode plate 505 to the reference ground potential 512. In this manner, the workpiece 109 is capacitively coupled to the reference ground potential 512 through the electrically conductive interior electrode plate 505. Otherwise, the backside plasma cleaning of the workpiece 109 using the system 500 is substantially the same as that described with regard to the system 300 of FIG. 3A.

FIG. 5B shows the system 500 in a configuration for performing the bevel edge plasma cleaning of the workpiece 109. In this configuration, the dielectric edge ring 201 is fully lowered such that the workpiece rests directly on the lower showerhead electrode plate 301. Also, in this configuration, the lower electrode assembly 304 and the configurable upper electrode assembly 510 are moved toward each other such that the top surface of the workpiece 109 is in close proximity to the configurable upper electrode assembly 510 so as to form the gap 113. In this configuration, the valve 502 is open so as to turn on the flow of process gas from the upper process gas supply 501 to the peripheral region of the workpiece 109. Also, in this configuration, the purge gas is supplied from the purge gas supply 117 to the gap 113 between the configurable upper electrode assembly 510 and the workpiece 109, so as to prevent reactive constituents of a plasma 513 from reaching the top surface of the workpiece 109.

Also, in the configuration of FIG. 5B, RF power is supplied from the RF power supply 123 to the lower showerhead electrode plate 301. The RF power propagates through transmission paths that extend from the lower showerhead electrode plate 301 to both the grounded outer base plate 137 and grounded upper electrode plate 107, thereby transforming the process gas supplied to the peripheral region of the workpiece 109 into the plasma 513. As this occurs, the purge gas flows radially outward through the gap 113 from the centrally located dispense location of the purge gas supply channel 115 toward the periphery of the workpiece 109, thereby preventing reactive constituents of the plasma 513 from entering the gap 113 and interacting with the top surface of the workpiece 109. Also, it should be understood that in the configuration of FIG. 5B, process gas is not supplied from the lower process gas supply 311 to the interior region 303 of the lower showerhead electrode plate 301.

Also, in the configuration of FIG. 5B, the switch 509 is set to electrically disconnect the electrically conductive interior electrode plate 505 from the reference ground potential 512, thereby causing the electrically conductive interior electrode plate 505 to have a floating electrical potential. In this manner, the workpiece 109 is not capacitively coupled to the reference ground potential 512, so as to prevent arcing or other undesirable phenomena within the gap 113, due to the closer proximity of the RF powered lower showerhead electrode plate 301 to the configurable upper electrode assembly 510. Also, in the configuration of FIG. 5B, the exhaust 131 is operated to draw process gases, purge gases, and plasma processing by-product materials away from the peripheral region of the workpiece 109 where the plasma 513 is generated to the exhaust port 133, as indicated by arrows 139.

FIG. 5C shows a variation of the semiconductor processing system 500 of FIG. 5A defined to use a remote plasma source 184, in accordance with one embodiment of the present invention. The remote plasma source 184 is defined to generate reactive constituents of the plasma 302 external to the chamber 101, and flow the reactive constituents of the plasma 302 through a conduit 180 to the interior region 303 of the lower showerhead electrode plate 301, as indicated by arrow 182, and ultimately to the region beneath the workpiece 109.

The process gas, purge gas, and plasma 302 reaction by-product materials are evacuated from the chamber 101 through the port 133 by way of the exhaust 131, as indicated by arrows 139. In various embodiments, the remote plasma source 184 is defined to generate reactive constituents of the plasma 302 using RF power, microwave power, or a combination thereof. Also, in various embodiments, the remote plasma source 184 is defined as either a capacitively coupled plasma source or an inductively coupled plasma source.

In various embodiments, RF power within a range extending from about 1 kW to about 10 kW is used to generate the plasma 302 in the remote plasma source 184. In some embodiments, RF power within a range extending from about 5 kW to about 8 kW is used to generate the plasma 302 in the remote plasma source 184. In some embodiments, RF power within a frequency range extending from about 2 MHz to about 60 MHz is used to generate the plasma 302 in the remote plasma source 184. In some embodiments, direct current (DC) power can also be applied to the lower showerhead electrode plate 301. Additionally, in some embodiments, multiple frequencies of RF power can be used to generate the plasma 302 within the remote plasma source 184 at either the same time or at different times, such as in a cyclical manner.

In some embodiments, the pressure of a process gas within the remote plasma source 184 is controlled within a range extending from about 0.1 T to about 10 T. In some embodiments, the pressure of the process gas within the remote plasma source 184 is controlled within a range extending from about 1 T to about 10 T. In some embodiments, the process gas is supplied to the remote plasma source 184 at a flow rate within a range extending from about 0.1 slm to about 5 slm. In some embodiments, the process gas is supplied to the remote plasma source 184 at a flow rate within a range extending from about 1 slm to about 5 slm.

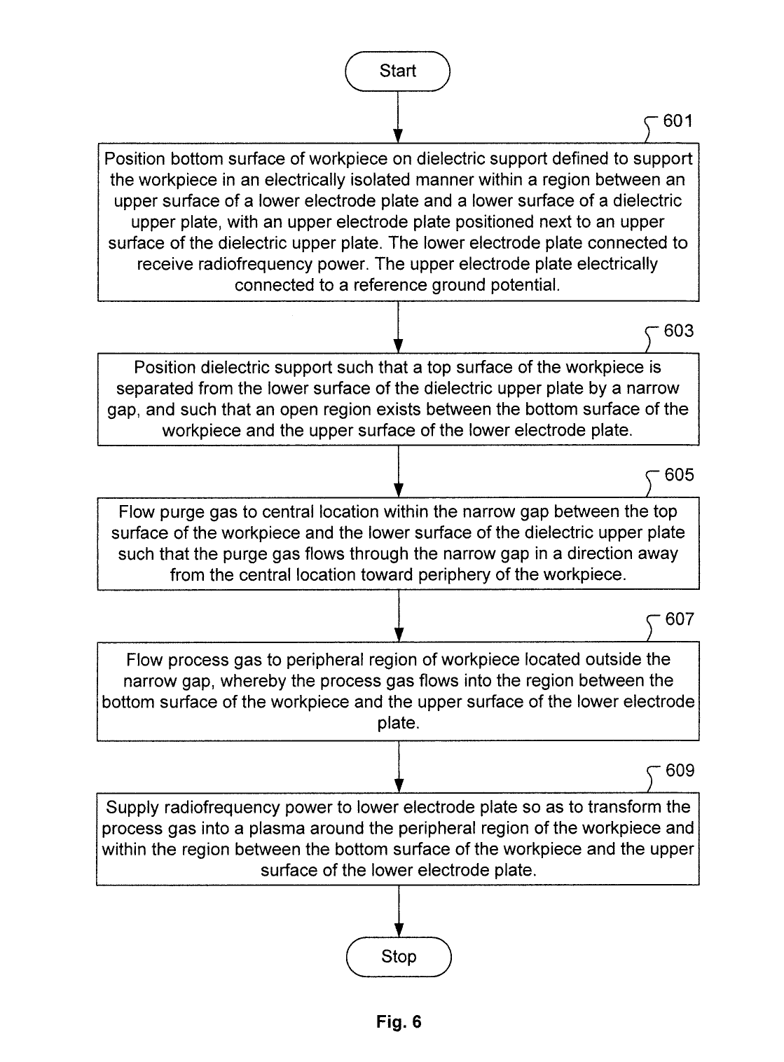

FIG. 6 shows a flowchart of a method for plasma cleaning a bottom surface of a workpiece, in accordance with one embodiment of the present invention. The method includes an operation 601 for positioning the bottom surface of the workpiece on a dielectric support defined to support the workpiece in an electrically isolated manner within a region between an upper surface of a lower electrode plate and a lower surface of a dielectric upper plate, with an upper electrode plate positioned next to an upper surface of the dielectric upper plate. The lower electrode plate is connected to receive radiofrequency power. The upper electrode plate is electrically connected to a reference ground potential. The method also includes an operation 603 for positioning the dielectric support such that a top surface of the workpiece is separated from the lower surface of the dielectric upper plate by a narrow gap, and such that an open region exists between the bottom surface of the workpiece and the upper surface of the lower electrode plate.

The method also includes an operation 605 for flowing a purge gas to a central location within the narrow gap between the top surface of the workpiece and the lower surface of the dielectric upper plate such that the purge gas flows through the narrow gap in a direction away from the central location toward a periphery of the workpiece. The method also includes an operation 607 for flowing a process gas to a peripheral region of the workpiece located outside the narrow gap, whereby the process gas flows into the region between the bottom surface of the workpiece and the upper surface of the lower electrode plate. It should be understood that flow of the purge gas through the narrow gap in the direction away from the central location toward the periphery of the workpiece prevents the process gas from flowing into the narrow gap and over the top surface of the workpiece.

The method also includes an operation 609 for supplying radiofrequency power to the lower electrode plate so as to transform the process gas into a plasma around the peripheral region of the workpiece, and within the region between the bottom surface of the workpiece and the upper surface of the lower electrode plate. The method can also include an operation for exhausting gases from the region above the upper surface of the lower electrode plate, so as to move plasma etching by-product materials away from the workpiece.

In one embodiment of the method, the dielectric support is defined as a set of dielectric lifting pins that extend through the lower electrode plate to support the workpiece in an electrically isolated manner within the region between the upper surface of the lower electrode plate and the lower surface of the dielectric upper plate. In this embodiment, positioning the dielectric support such that the top surface of the workpiece is separated from the lower surface of the dielectric upper plate by the narrow gap in operation 603 is performed by moving the set of dielectric lifting pins toward the lower surface of the dielectric upper plate.

In another embodiment of the method, the dielectric support is defined as a dielectric edge ring having an annular shape with an upper surface defined to contact and support a peripheral region of the bottom surface of the workpiece. The dielectric edge ring includes vents defined to allow for flow of the process gas into the region between the bottom surface of the workpiece and the upper surface of the lower electrode plate and to allow for exhausting gases from the region above the upper surface of the lower electrode plate.

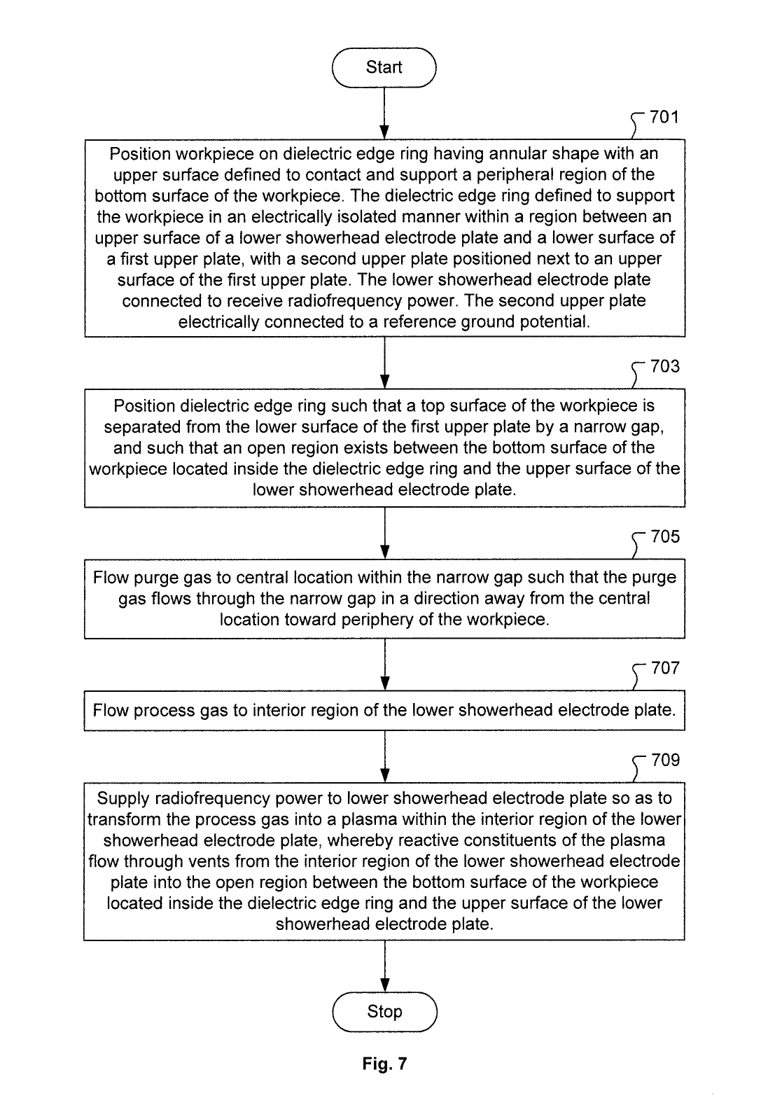

FIG. 7 shows a flowchart of a method for plasma cleaning a bottom surface of a workpiece, in accordance with one embodiment of the present invention. The method includes an operation 701 for positioning the workpiece on a dielectric edge ring having an annular shape with an upper surface defined to contact and support a peripheral region of the bottom surface of the workpiece. The dielectric edge ring is defined to support the workpiece in an electrically isolated manner within a region between an upper surface of a lower showerhead electrode plate and a lower surface of a first upper plate. A second upper plate is positioned next to an upper surface of the first upper plate. The lower showerhead electrode plate is connected to receive radiofrequency power. The second upper plate electrically connected to a reference ground potential.

The method also includes an operation 703 for positioning the dielectric edge ring such that a top surface of the workpiece is separated from the lower surface of the first upper plate by a narrow gap, and such that an open region exists between the bottom surface of the workpiece located inside the dielectric edge ring and the upper surface of the lower showerhead electrode plate. The method also includes an operation 705 for flowing a purge gas to a central location within the narrow gap, such that the purge gas flows through the narrow gap in a direction away from the central location toward a periphery of the workpiece. The method also includes an operation 707 for flowing a process gas to an interior region of the lower showerhead electrode plate.

The method also includes an operation 709 for supplying radiofrequency power to the lower showerhead electrode plate so as to transform the process gas into a plasma within the interior region of the lower showerhead electrode plate, whereby reactive constituents of the plasma flow through vents from the interior region of the lower showerhead electrode plate into the open region between the bottom surface of the workpiece located inside the dielectric edge ring and the upper surface of the lower showerhead electrode plate. The method can also include an operation for exhausting gases from the open region between the bottom surface of the workpiece located inside the dielectric edge ring and the upper surface of the lower showerhead electrode plate through vents defined in the dielectric edge ring.

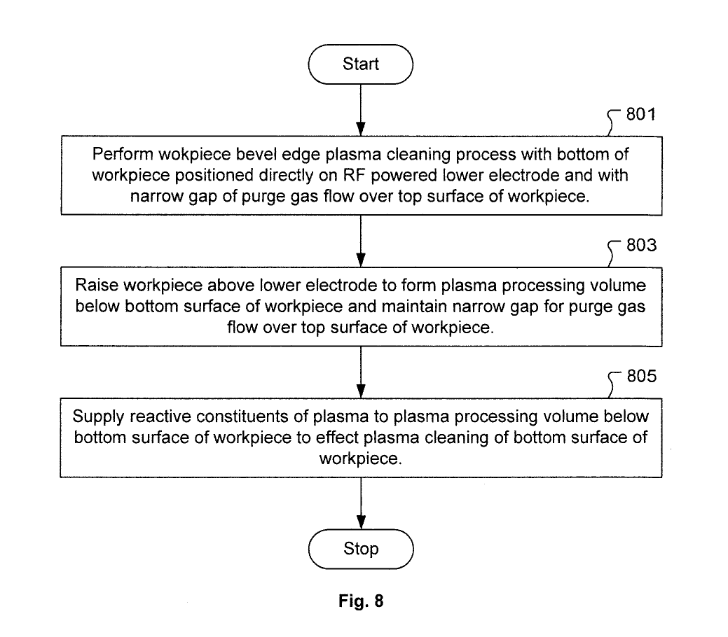

FIG. 8 shows a flowchart of a method for performing both a bevel edge plasma cleaning process and backside cleaning process on a workpiece within a common, i.e., single, plasma processing system, in accordance with one embodiment of the present invention. The method includes an operation 801 in which a bevel edge plasma cleaning process is performed on the workpiece with the bottom of the workpiece positioned directly on an RF powered lower electrode and with a narrow gap of purge gas flow provided over a top surface of the workpiece. In operation 801, an upper structural member is provided above the workpiece to form the narrow gap of purge gas flow over the top surface of the workpiece. In one example embodiment, the bevel edge plasma cleaning process of operation 801 is performed using a capacitively coupled plasma generated by RF power at 13.56 MHz. However, it should be understood that in other embodiments, the bevel edge plasma cleaning process can be performed using RF power at other frequencies, powers, and duty cycles, and with any suitable process gas.

After the bevel edge plasma cleaning process is completed in operation 801, an operation 803 is performed in which the workpiece is raised above the lower electrode to form a plasma processing volume below the bottom surface of the workpiece. Also, in operation 803, the narrow gap for purge gas flow is maintained over top surface of workpiece. In one embodiment, the workpiece is raised above the lower electrode using dielectric lifting pins, such as described with regard to FIG. 1A. In another embodiment, the workpiece is raised above the lower electrode using a vented dielectric edge ring, such as described with regard to FIG. 2A.

The method continues with an operation 805 for supplying reactive constituents of a plasma to the plasma processing volume below the bottom surface of workpiece to effect plasma cleaning of bottom surface of workpiece. In one embodiment, operation 805 includes generating reactive constituents of the plasma using a remotely generated plasma, and delivering the reactive constituents of the plasma to the plasma processing volume below the bottom surface of workpiece. In another embodiment, a process gas is flowed to the plasma processing volume below the bottom surface of workpiece, and RF power is applied to transform the process gas into a plasma within the plasma processing volume below the bottom surface of workpiece. In either embodiment, the reactive constituents of the plasma present within the plasma processing volume below the bottom surface of workpiece are allowed to interact with and remove a target film or material from the bottom surface of the workpiece. Also, during operation 805, a flow of purge gas is maintained over the top surface of the workpiece to prevent reactive constituents of the plasma or any other by-product materials from contacting and interacting with the top surface of the workpiece.

It should be appreciated that the various semiconductor processing systems disclosed herein provide for performance of both bevel edge plasma cleaning processes and backside plasma cleaning processes in a single tool, i.e., single chamber. Also, it should be appreciated that the backside plasma cleaning processes discussed herein are especially useful in removing carbon, photoresist, and other carbon-related polymers from the bottom surface of the workpiece, as these materials are difficult to remove in alternative wet clean processes. Additionally, it should be appreciated that the backside plasma cleaning processes discussed herein can provide for higher cleaning throughput than the alternative wet clean processes, because of the higher etch rates achievable with the plasma in the backside plasma cleaning processes.

While this invention has been described in terms of several embodiments, it will be appreciated that those skilled in the art upon reading the preceding specifications and studying the drawings will realize various alterations, additions, permutations and equivalents thereof. Therefore, it is intended that the present invention includes all such alterations, additions, permutations, and equivalents as fall within the true spirit and scope of the invention.

What is claimed is:

1. A semiconductor processing system, comprising:
a lower electrode plate;
a radiofrequency power supply connected to supply radiofrequency power to the lower electrode plate;
a dielectric upper plate positioned parallel to and spaced apart from the lower electrode plate;
an upper electrode plate positioned next to the dielectric upper plate such that the dielectric upper plate is located between the lower electrode plate and the upper electrode plate, the upper electrode plate electrically connected to a reference ground potential;
a dielectric support defined to support a workpiece in an electrically isolated manner within a region between the lower electrode plate and the dielectric upper plate;
a purge gas supply channel formed to supply a purge gas to the region between the lower electrode plate and the dielectric upper plate at a central location of the dielectric upper plate; and
a process gas supply channel formed to supply a process gas to the region between the lower electrode plate and the dielectric upper plate at a periphery of the dielectric upper plate,
wherein the dielectric support is defined to position the workpiece at a position proximate to and substantially parallel to the dielectric upper plate such that the purge gas is made to flow from the purge gas supply channel over a top surface of the workpiece between the dielectric upper plate and the top surface of the workpiece so as to prevent the process gas from flowing over the top surface of the workpiece and so as to cause the process gas to flow around a peripheral edge of the workpiece and below the workpiece into a region between the lower electrode plate and a bottom surface of the workpiece, when the workpiece is present on the dielectric support.

2. A semiconductor processing system as recited in claim 1, wherein the purge gas supply channel is formed through both the upper electrode plate and the dielectric upper plate, and wherein the purge gas supply channel is fluidly connected to a purge gas supply containing an inert gas.

3. A semiconductor processing system as recited in claim 1, wherein the process gas supply channel is formed through the upper electrode plate and includes an open region between the upper electrode plate and dielectric upper plate, and wherein the process gas supply channel is fluidly connected to a process gas supply containing the process gas, the process gas defined to transform into a plasma when exposed to the radiofrequency power.

4. A semiconductor processing system as recited in claim 1, wherein the dielectric support is defined as a set of dielectric lifting pins that extend through the lower electrode plate to support the workpiece in an electrically isolated manner within the region between the lower electrode plate and the dielectric upper plate.

5. A semiconductor processing system as recited in claim 4, wherein the set of dielectric lifting pins are defined to extend in a controllable manner into the region between the lower electrode plate and the dielectric upper plate so as to control a distance between the top surface of the workpiece and the dielectric upper plate when the workpiece is present on the set of dielectric lifting pins.

6. A semiconductor processing system as recited in claim 1, wherein the dielectric support is defined as a dielectric edge ring having an annular shape with an upper surface defined to contact and support a peripheral region of the bottom surface of the workpiece.

7. A semiconductor processing system as recited in claim 6, wherein the dielectric edge ring includes vents defined to allow for flow of the process gas from an output of the process gas supply channel to the region between the lower electrode plate and the bottom surface of the workpiece, when the workpiece is present on the dielectric edge ring.

8. A semiconductor processing system as recited in claim 7, wherein the dielectric edge ring is defined to extend in a controllable manner into the region between the lower electrode plate and the dielectric upper plate so as to control a distance between the top surface of the workpiece and the dielectric upper plate when the workpiece is present on the dielectric edge ring.

9. A method for plasma cleaning a peripheral region and a bottom surface of a workpiece, comprising:
positioning the bottom surface of the workpiece on a dielectric support defined to support the workpiece in an electrically isolated manner within a region between an upper surface of a lower electrode plate and a lower surface of a dielectric upper plate, with an upper electrode plate positioned next to an upper surface of the dielectric upper plate, the lower electrode plate connected to receive radiofrequency power, the upper electrode plate electrically connected to a reference ground potential;
positioning the dielectric support such that a top surface of the workpiece is separated from the lower surface of the dielectric upper plate by a narrow gap, and such that an open region exists between the bottom surface of the workpiece and the upper surface of the lower electrode plate;
flowing a purge gas to a central location within the narrow gap between the top surface of the workpiece and the lower surface of the dielectric upper plate such that the purge gas flows through the narrow gap in a direction away from the central location toward a periphery of the workpiece;
flowing a process gas to a peripheral region of the workpiece located outside the narrow gap, whereby the process gas flows into the region between the bottom surface of the workpiece and the upper surface of the lower electrode plate; and
supplying radiofrequency power to the lower electrode plate so as to transform the process gas into a plasma around the peripheral region of the workpiece and within the region between the bottom surface of the workpiece and the upper surface of the lower electrode plate.

10. A method for plasma cleaning a peripheral region and a bottom surface of a workpiece as recited in claim 9, wherein flow of the purge gas through the narrow gap in the direction away from the central location toward the periphery of the workpiece prevents the process gas from flowing into the narrow gap and over the top surface of the workpiece.

11. A method for plasma cleaning a peripheral region and a bottom surface of a workpiece as recited in claim 10, further comprising:
exhausting gases from the region above the upper surface of the lower electrode plate so as to move plasma etching by-product materials away from the workpiece.

12. A method for plasma cleaning a peripheral region and a bottom surface of a workpiece as recited in claim 11, wherein the dielectric support is defined as a set of dielectric lifting pins that extend through the lower electrode plate to support the workpiece in an electrically isolated manner within the region between the upper surface of the lower electrode plate and the lower surface of the dielectric upper plate.

13. A method for plasma cleaning a peripheral region and a bottom surface of a workpiece as recited in claim 12, wherein positioning the dielectric support such that the top surface of the workpiece is separated from the lower surface of the dielectric upper plate by the narrow gap is performed by moving the set of dielectric lifting pins toward the lower surface of the dielectric upper plate.

14. A method for plasma cleaning a peripheral region and a bottom surface of a workpiece as recited in claim 11, wherein the dielectric support is defined as a dielectric edge ring having an annular shape with an upper surface defined to contact and support a peripheral region of the bottom surface of the workpiece, wherein the dielectric edge ring includes vents defined to allow for flow of the process gas into the region between the bottom surface of the workpiece and the upper surface of the lower electrode plate and to allow for exhausting gases from the region above the upper surface of the lower electrode plate.

15. A semiconductor processing system, comprising:
a lower showerhead electrode plate having an interior region for transforming a process gas into a plasma, the lower showerhead electrode plate having a number of vents extending from an upper surface of the lower showerhead plate to the interior region;
a process gas supply channel formed to supply the process gas to the interior region of the lower showerhead electrode plate;
a radiofrequency power supply connected to supply radiofrequency power to the lower showerhead electrode plate so as to transform the process gas into the plasma within the interior region of the lower showerhead electrode plate;
a first upper plate positioned parallel to and spaced apart from the lower showerhead electrode plate;
a second upper plate positioned next to the first upper plate such that the first upper plate is located between the lower showerhead electrode plate and the second upper plate, the second upper plate electrically connected to a reference ground potential;
a dielectric edge ring having an annular shape with an upper surface defined to contact and support a peripheral region of a bottom surface of a workpiece and support the workpiece in an electrically isolated manner within a region between the upper surface of the lower showerhead electrode plate and a lower surface of the first upper plate; and
a purge gas supply channel formed to supply a purge gas to the region between the upper surface of the lower showerhead electrode plate and the lower surface of the first upper plate at a central location of the first upper plate,
wherein the dielectric edge ring is defined to position the workpiece proximate to and substantially parallel to the first upper plate such that the purge gas is made to flow from the purge gas supply channel over a top surface of the workpiece between the lower surface of the first upper plate and the top surface of the workpiece so as to prevent reactive constituents of the plasma from reaching the top surface of the workpiece, when the workpiece is present on the dielectric edge ring.

16. A semiconductor processing system as recited in claim 15, wherein the first upper plate is formed of a dielectric material.

17. A semiconductor processing system as recited in claim 15, wherein the first upper plate is formed of an electrically conductive material.

18. A semiconductor processing system as recited in claim 15, wherein the dielectric edge ring includes vents defined to allow for exhausting gases from a region below a bottom surface of the workpiece and above the upper surface of the lower showerhead plate.

19. A method for plasma cleaning a bottom surface of a workpiece, comprising:
positioning the workpiece on a dielectric edge ring having an annular shape with an upper surface defined to contact and support a peripheral region of the bottom surface of the workpiece, the dielectric edge ring defined to support the workpiece in an electrically isolated manner within a region between an upper surface of a lower showerhead electrode plate and a lower surface of a first upper plate, with a second upper plate positioned next to an upper surface of the first upper plate, the lower showerhead electrode plate connected to receive radiofrequency power, the second upper plate electrically connected to a reference ground potential;
positioning the dielectric edge ring such that a top surface of the workpiece is separated from the lower surface of the first upper plate by a narrow gap, and such that an open region exists between the bottom surface of the workpiece located inside the dielectric edge ring and the upper surface of the lower showerhead electrode plate;
flowing a purge gas to a central location within the narrow gap such that the purge gas flows through the narrow gap in a direction away from the central location toward a periphery of the workpiece;
flowing a process gas to an interior region of the lower showerhead electrode plate; and
supplying radiofrequency power to the lower showerhead electrode plate so as to transform the process gas into a plasma within the interior region of the lower showerhead electrode plate, whereby reactive constituents of the plasma flow through vents from the interior region of the lower showerhead electrode plate into the open region between the bottom surface of the workpiece located inside the dielectric edge ring and the upper surface of the lower showerhead electrode plate.

20. A method for plasma cleaning a bottom surface of a workpiece as recited in claim 19, further comprising:
exhausting gases from the open region between the bottom surface of the workpiece located inside the dielectric edge ring and the upper surface of the lower showerhead electrode plate through vents defined in the dielectric edge ring.
